(19) United States
(12) Patent Application Publication
(10) Pub. No.: US 2024/0373767 A1
(43) Pub. Date: Nov. 7, 2024

(54) SEMICONDUCTOR STRUCTURE AND MANUFACTURING METHOD THEREOF

(71) Applicants: TAIWAN SEMICONDUCTOR MANUFACTURING COMPANY, LTD., Hsinchu (TW); NATIONAL TAIWAN UNIVERSITY, TAIPEI (TW)

(72) Inventors: Yu-Ting HUANG, Changhua City (TW); Zih-Syuan HUANG, Yunlin County (TW); Jin-Bin YANG, Taichung City (TW); I-Chih NI, New Taipei City (TW); Chih-I WU, Taipei City (TW)

(73) Assignees: TAIWAN SEMICONDUCTOR MANUFACTURING COMPANY, LTD., Hsinchu (TW); NATIONAL TAIWAN UNIVERSITY, TAIPEI (TW)

(21) Appl. No.: 18/310,934

(22) Filed: May 2, 2023

(51) Int. Cl. H10N 70/00; H10B 63/00

(52) U.S. Cl. CPC H10N 70/8828; H10B 63/34; H10N 70/023; H10N 70/063; H10N 70/841; H10N 70/8822

(57) ABSTRACT

A method includes forming a first electrode layer on a substrate; depositing a transition metal layer on the first electrode layer, introducing a chalcogen precursor around the transition metal layer; performing a plasma treatment to ionize the chalcogen precursor around the transition metal layer to convert the transition metal layer into a transition metal dichalcogenide (TMDC) layer at a temperature lower than about 400° C.; forming a second electrode layer on the TMDC layer.

### BACKGROUND

Semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed.

In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flowchart of a method for forming a semiconductor structure in accordance with some embodiments of the present disclosure.

FIGS. 2A-2H illustrate a method in various stages of forming a semiconductor structure in accordance with some embodiments of the present disclosure.

FIG. 3 is a flowchart of a method for forming a semiconductor structure in accordance with some embodiments of the present disclosure.

FIGS. 4A-4L illustrate a method in various stages of forming a semiconductor structure in accordance with some embodiments of the present disclosure, in which FIGS. 4G and 4I illustrate cross-sectional views obtained from reference cross-sections C4-C4′ in FIGS. 4F and 4H, respectively.

FIG. 5 is a schematic diagram illustrating a method in various stages of forming a semiconductor structure in accordance with some embodiments of the present disclosure.

FIGS. 6A, 7A, and 8A are schematic diagrams of semiconductor structures in accordance with some embodiments of the present disclosure; FIGS. 6B-6M illustrate experimental results of the semiconductor structure in FIG. 6A; FIGS. 7B-7E illustrate experimental results of the semiconductor structure in FIG. 7A; and FIGS. 8B-8D illustrate experimental results of the semiconductor structure in FIG. 8A.

FIG. 9A illustrates a circuit diagram in accordance with some embodiments of the present disclosure; and FIG. 9B is a schematic diagram of a semiconductor structure corresponding to FIG. 9A.

FIGS. 10A-10Q illustrate a method in various stages of forming a semiconductor structure in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around,” “about,” “approximately,” or “substantially” may mean within 20 percent, or within 10 percent, or within 5 percent of a given value or range. One skilled in the art will realize, however, that the value or range recited throughout the description are merely examples, and may be reduced with the down-scaling of the integrated circuits. Numerical quantities given herein are approximate, meaning that the term “around,” “about,” “approximately,” or “substantially” can be inferred if not expressly stated.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

A resistive random access memory (RRAM) device including a resistive switching layer can be used in a system in which a persistent storage is required. However, forming the resistive switching layer may be performed at a temperature higher than about 400° C. or a operation time duration greater than about 30 minutes which may be over a back-end-of-line (BEOL) thermal budget, which in turn impacts the performance of the IC structure. In addition, the resistive switching layer growing on a metal and formed by a high-temperature (e.g. higher than about 400° C.) thermal chemical vapor deposition (CVD) process may need to conduct an additional transferring process to transfer the growing resistive switching layer from the metal to a target substrate, such that the transferring process may damage elements on the IC structure, which in turn deteriorates the performance of the IC structure. In some embodiments, the resistive switching layer may be made of a toxic material, such as halide perovskite (e.g., CH₃NH₃PbI₃, CH₃NH₃SnI₃, CsSnCI₃, CsPbI₃), which may deteriorate an environment.

Therefore, the present disclosure in various embodiments provides a plasma-enhanced chemical vapor deposition (PECVD) process performed at a low-temperature (e.g. lower than about 400° C.) and a low-process time duration (e.g. lower than about 30 minutes) with a chalcogen precursor to form a resistive switching layer including a transition metal dichalcogenide (TMDC) material. Because the formation of the resistive switching layer can be performed at a temperature lower about 400° C. and a process time duration lower about 30 minutes, a lower thermal budget to synthesize the resistive switching layer in the RRAM device is reached, such that the performance of an IC structure can be improved. For example, the resistive switching layer can be formed on the bottom electrode of RRAM device in the BEOL process with a temperature below 400° C. and without damaging the elements in the IC structure, which in turn increases the reliability of the IC structure. In addition, the resistive switching layer is made of the TMDC material, which in turn decreases a thickness of the resistive switching layer and acts as a nontoxic material to be environmentally friendly. Furthermore, because the resistive switching layer can be grown on the bottom electrode of RRAM device directly, there is no need to perform an additional transferring process on the resistive switching layer, and thus fabrication of the RRAM device structure will not result in additional processes that may damage the bottom electrode of the RRAM device and hence additional cost. Moreover, the RRAM device having a resistive switching layer including the TMDC material has a low operating voltage, which in turn improves the performance of the RRAM device.

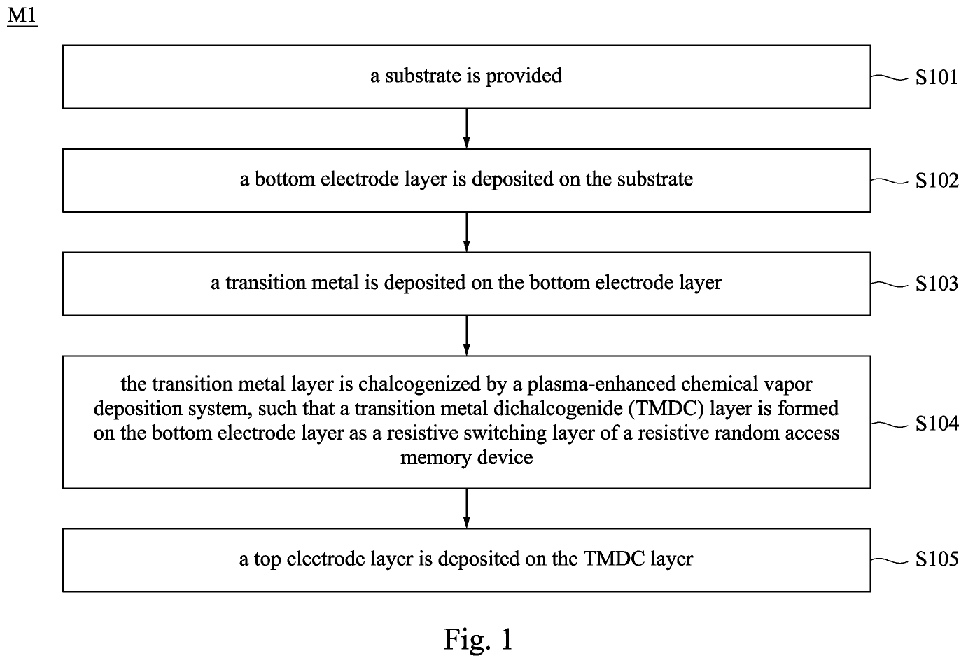

Referring now to FIG. 1, illustrated is a flowchart of an exemplary method M1 for fabrication of a semiconductor structure in accordance with some embodiments. The method M1 includes a relevant part of the entire manufacturing process. It is understood that additional operations may be provided before, during, and after the operations shown by FIG. 1, and some of the operations described below can be replaced or eliminated for additional embodiments of the method. The order of the operations/processes may be interchangeable. The method M1 includes fabrication of a semiconductor structure. However, the fabrication of the semiconductor structure is merely an example for describing the manufacturing process according to some embodiments of the present disclosure.

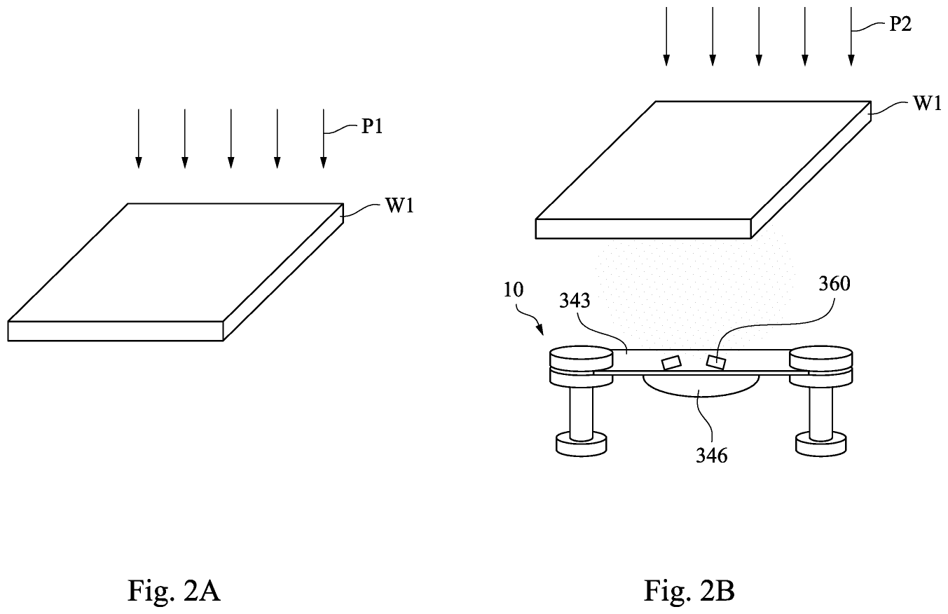

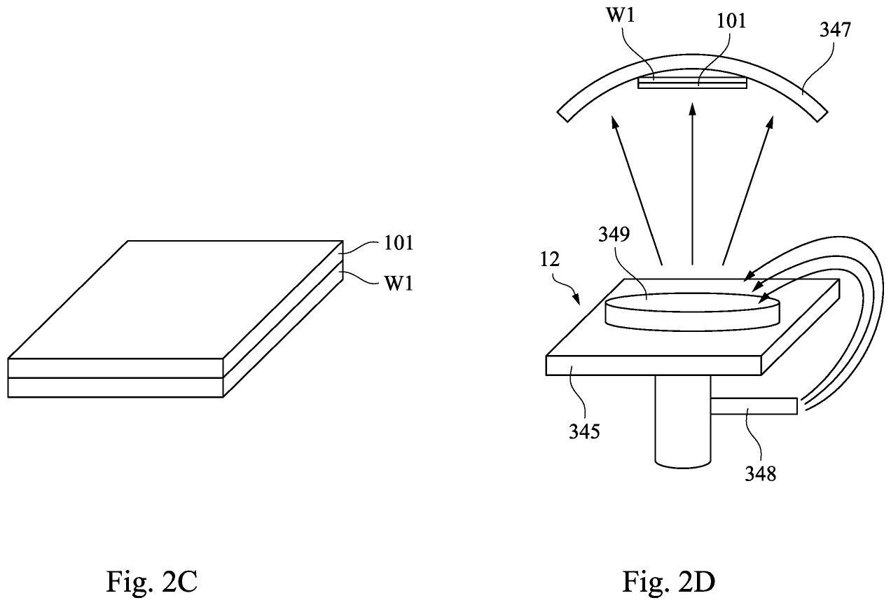

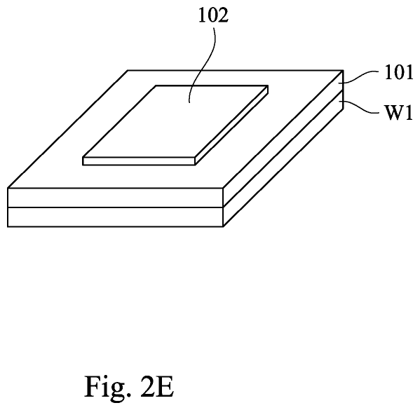

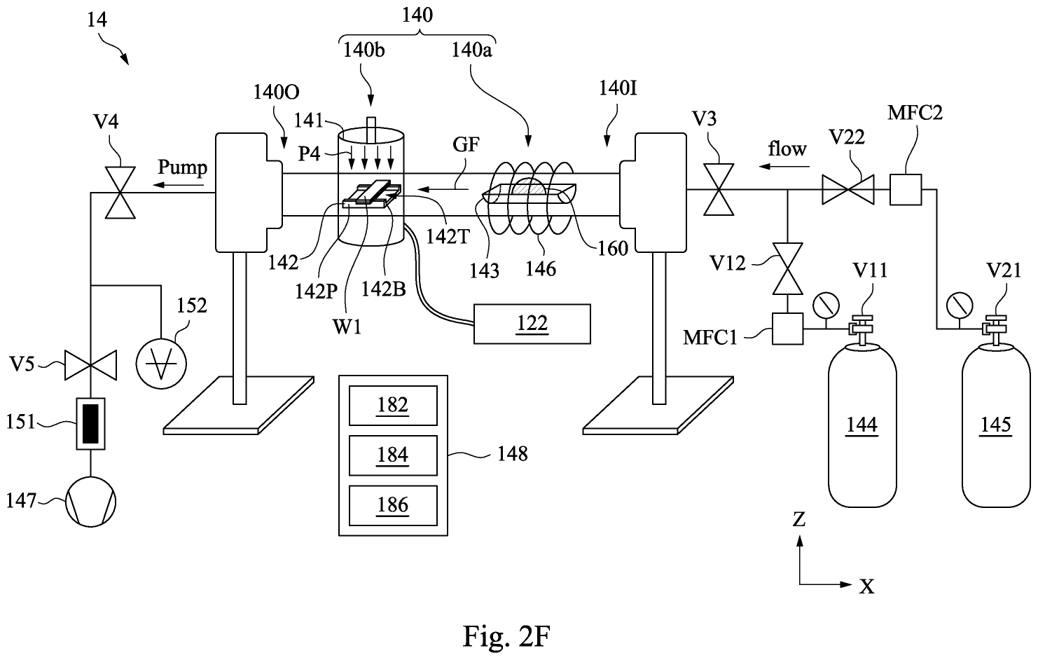

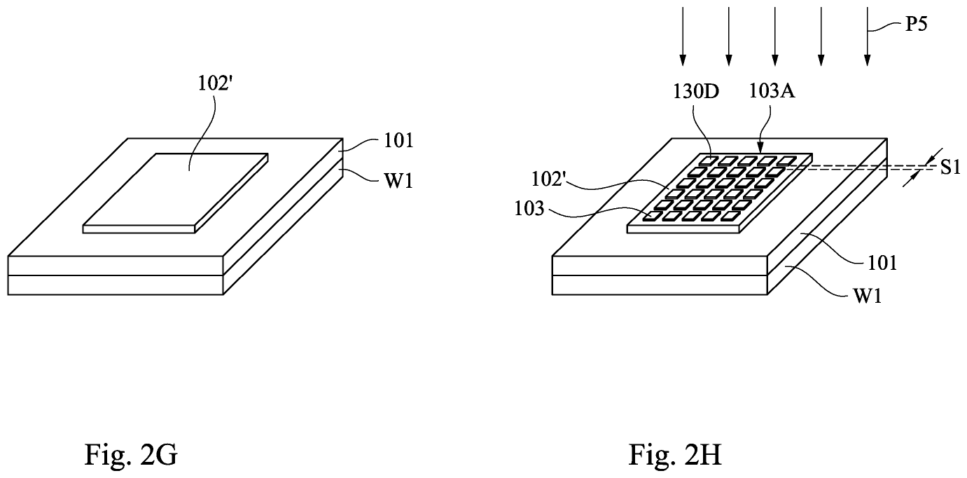

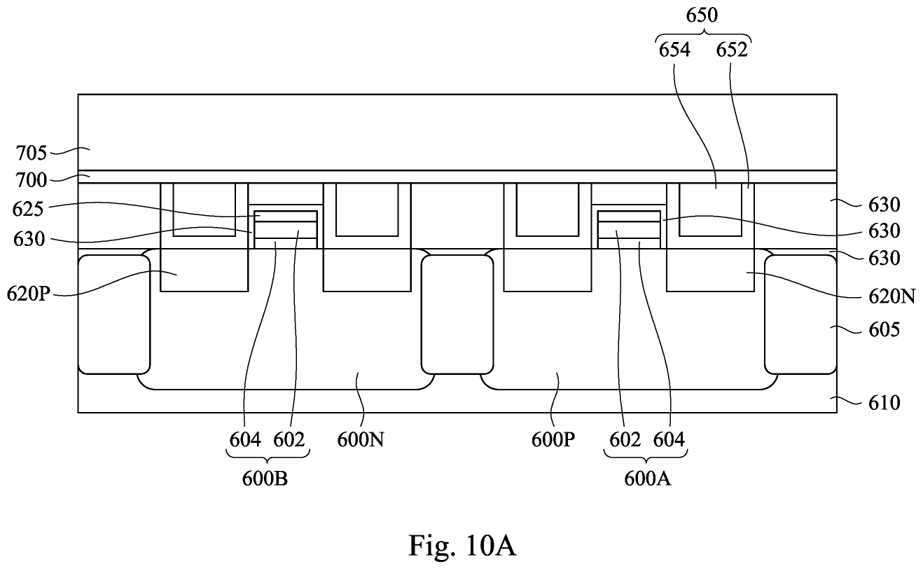

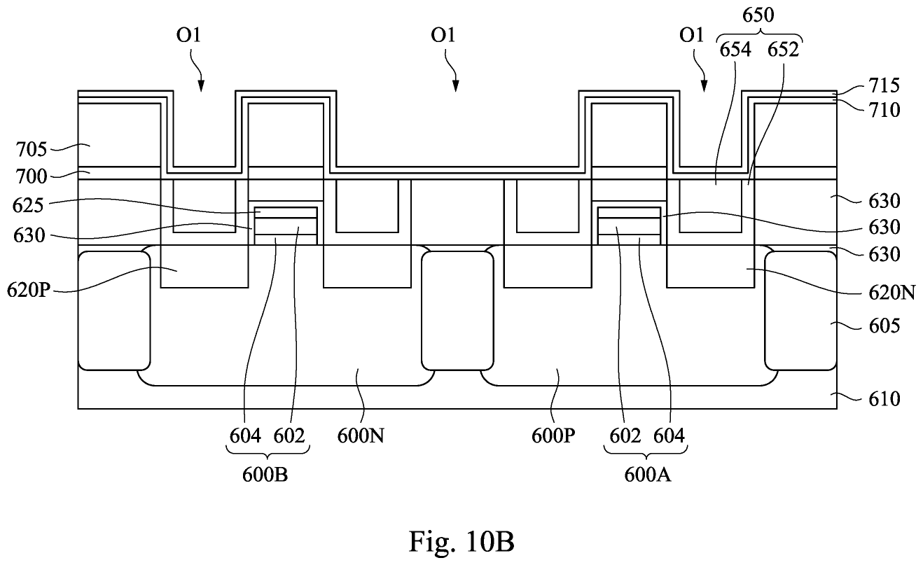

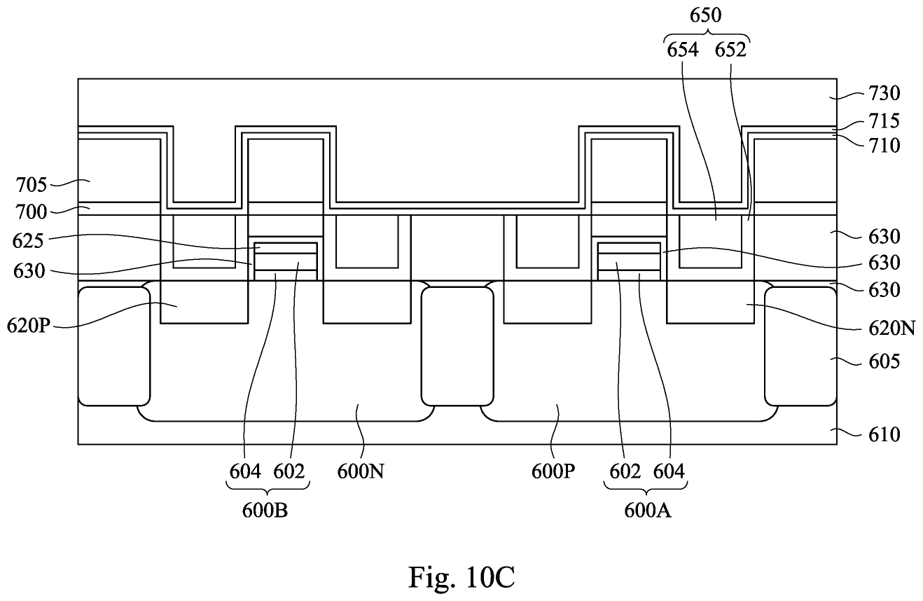

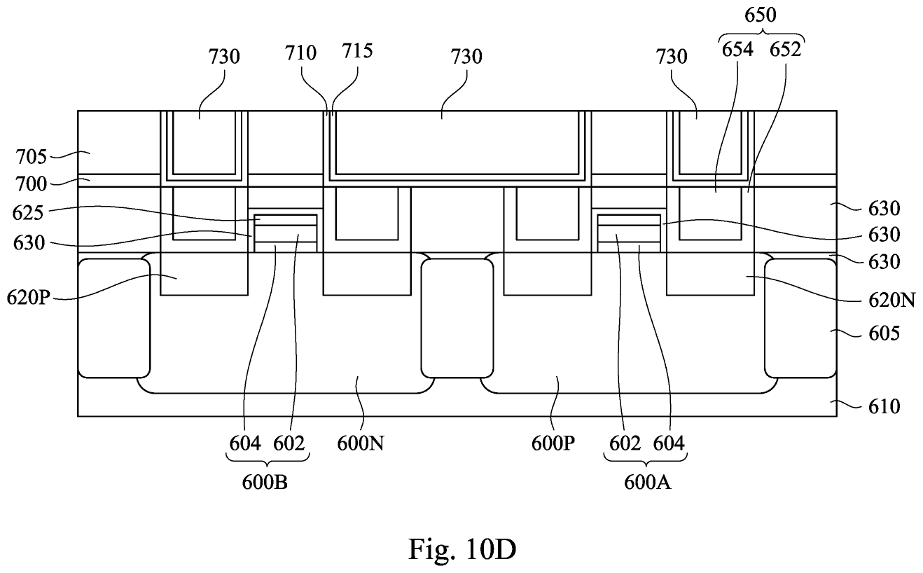

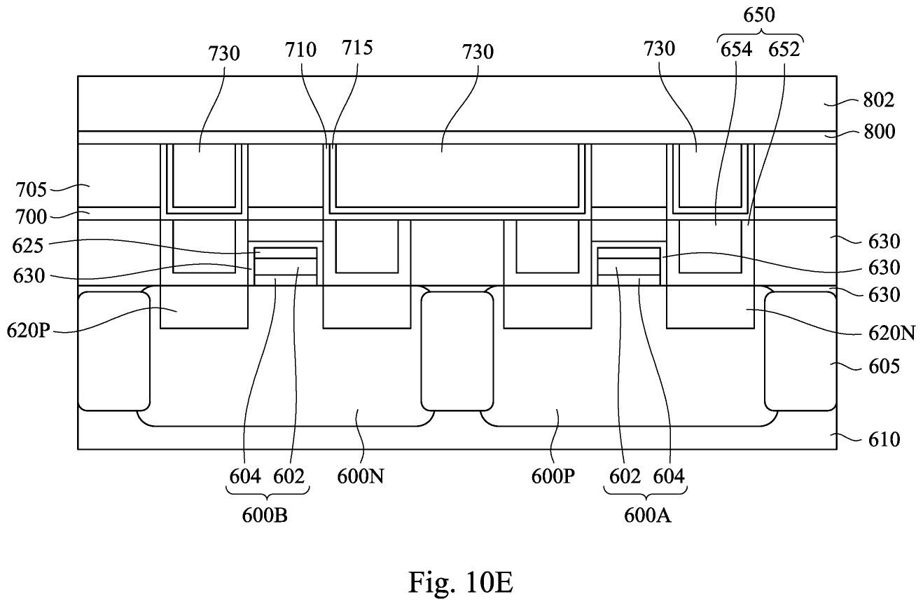

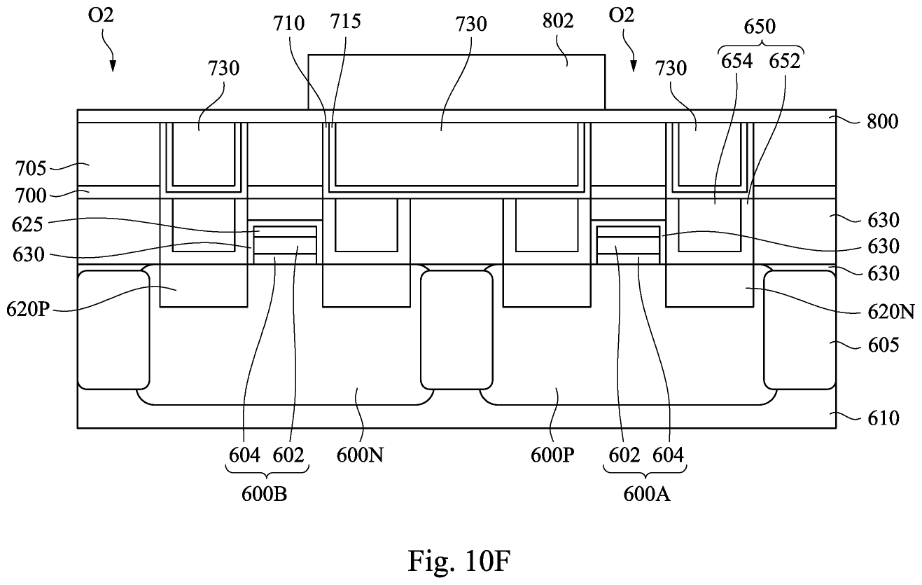

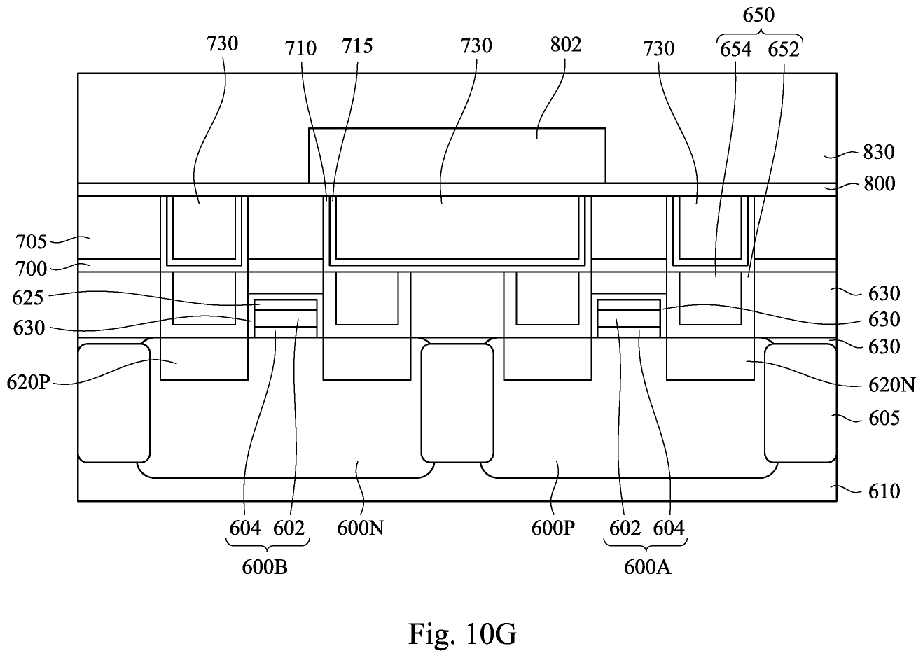

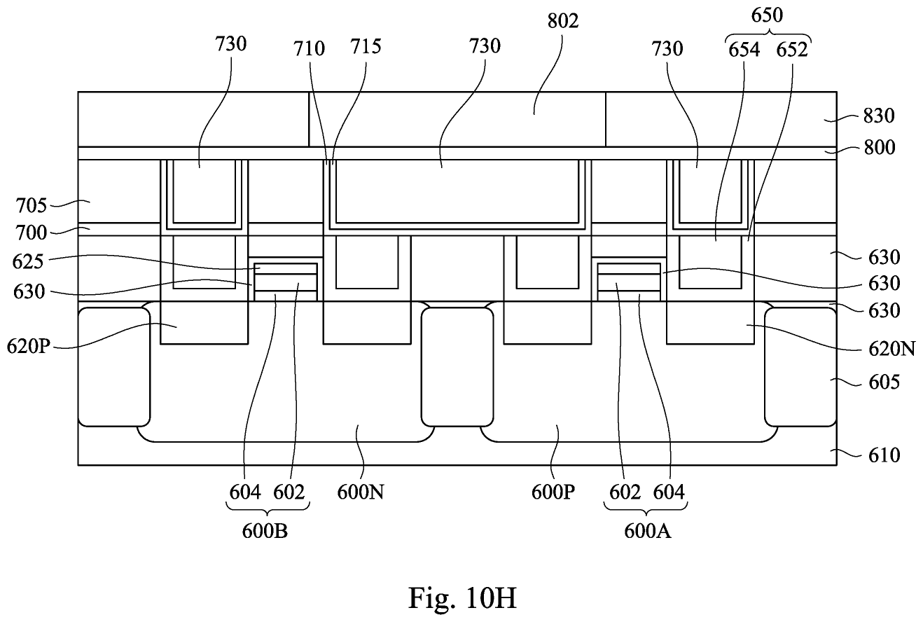

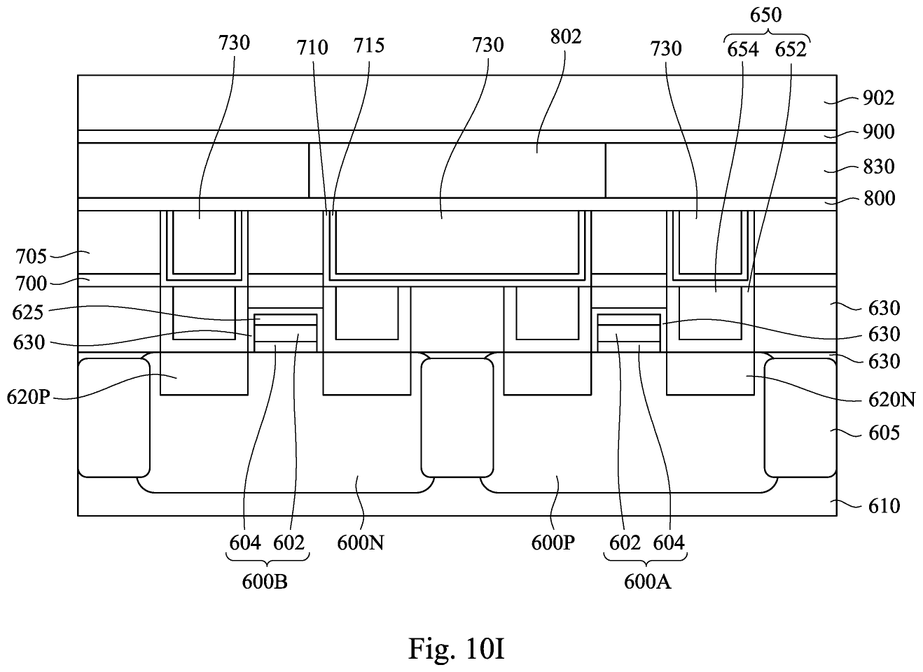

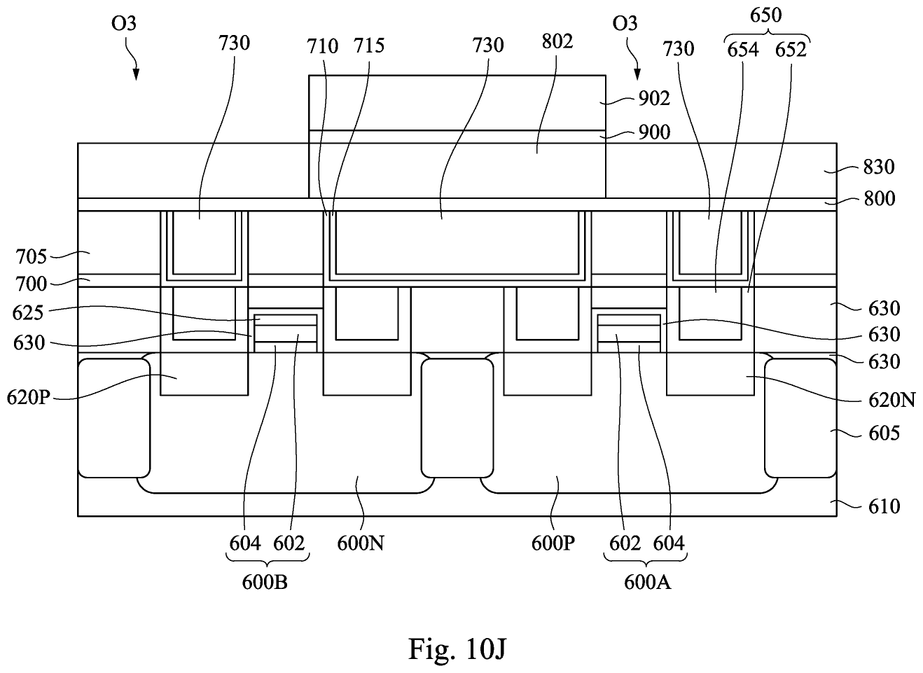

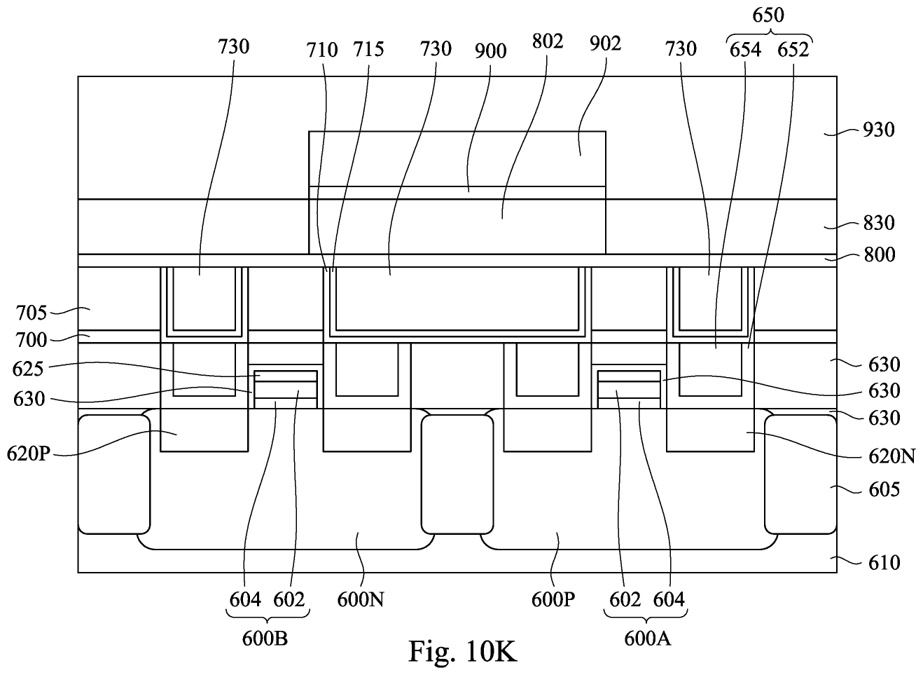

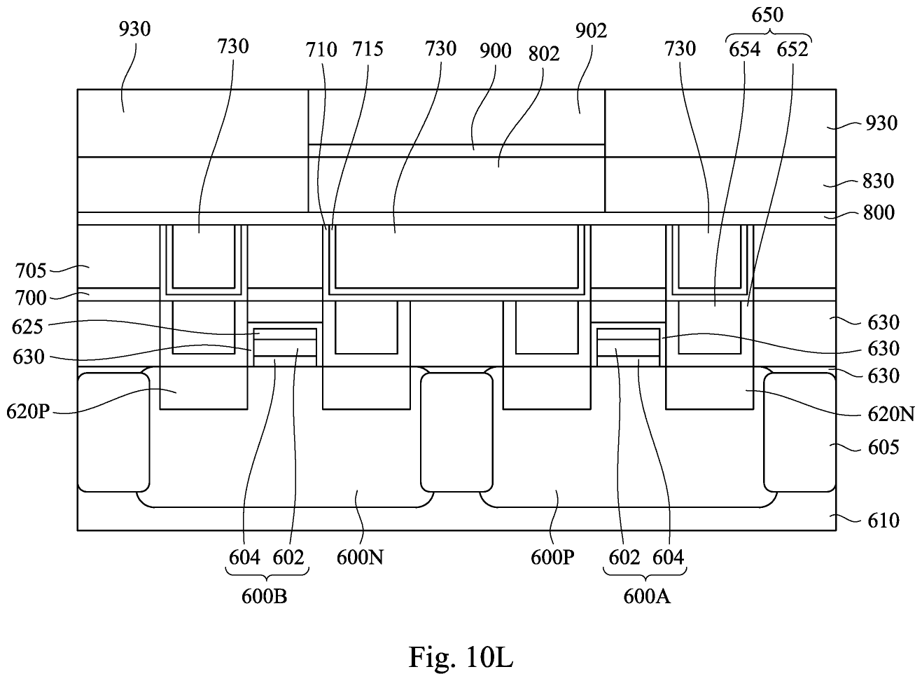

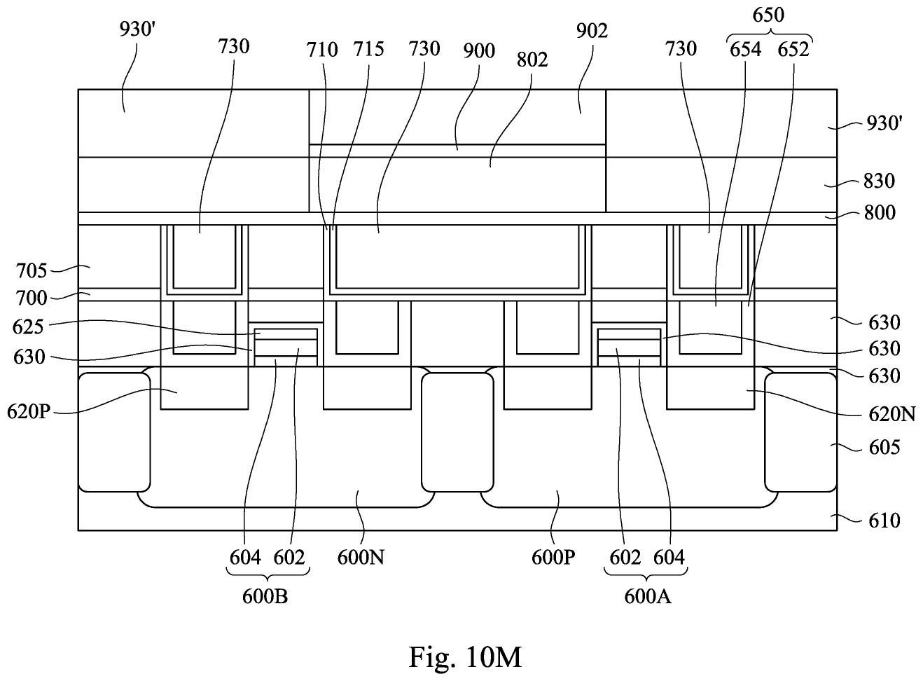

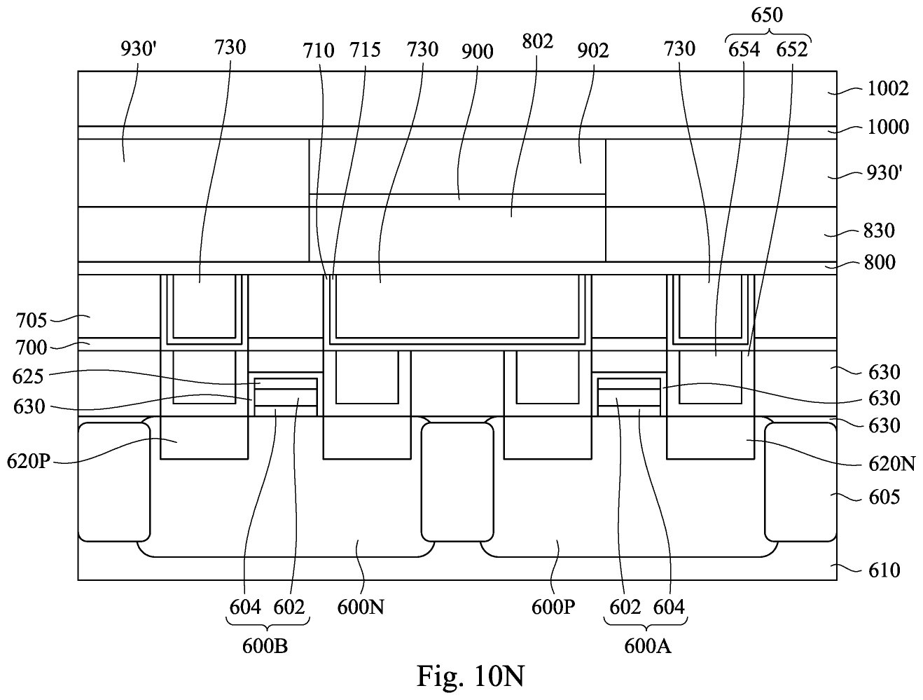

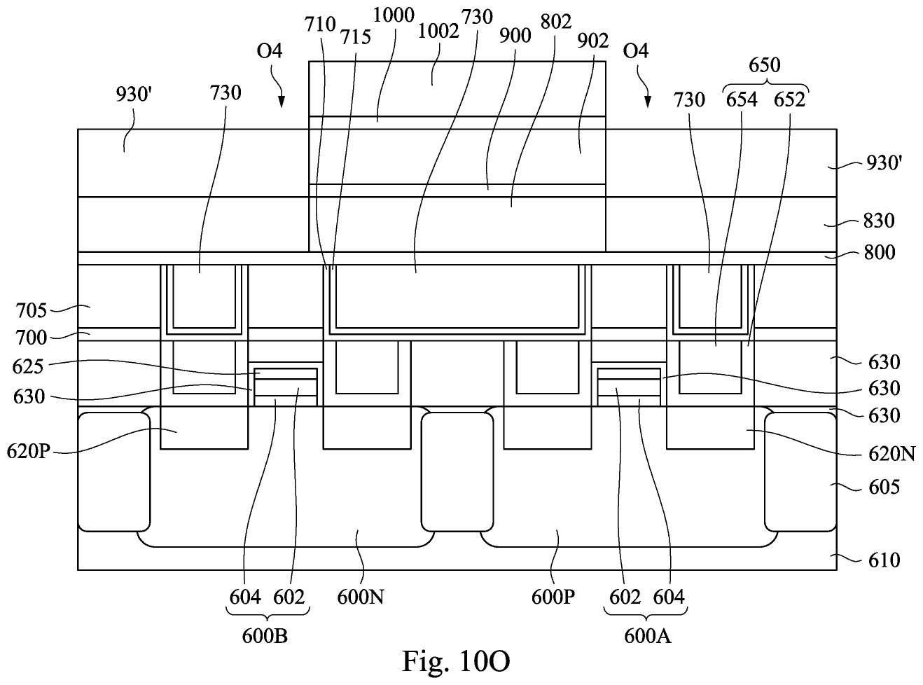

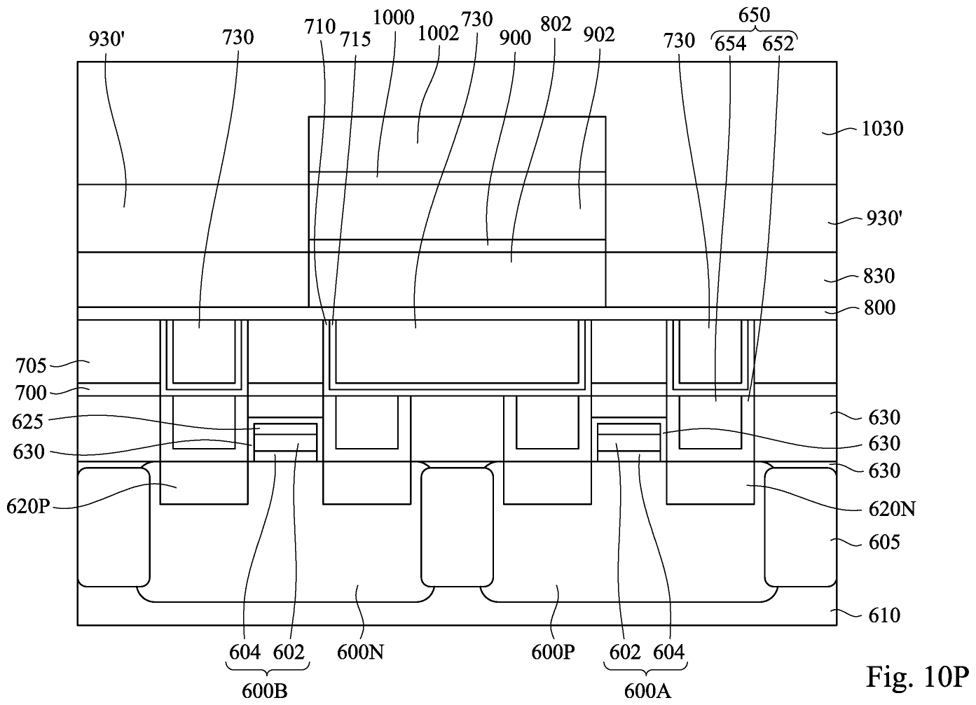

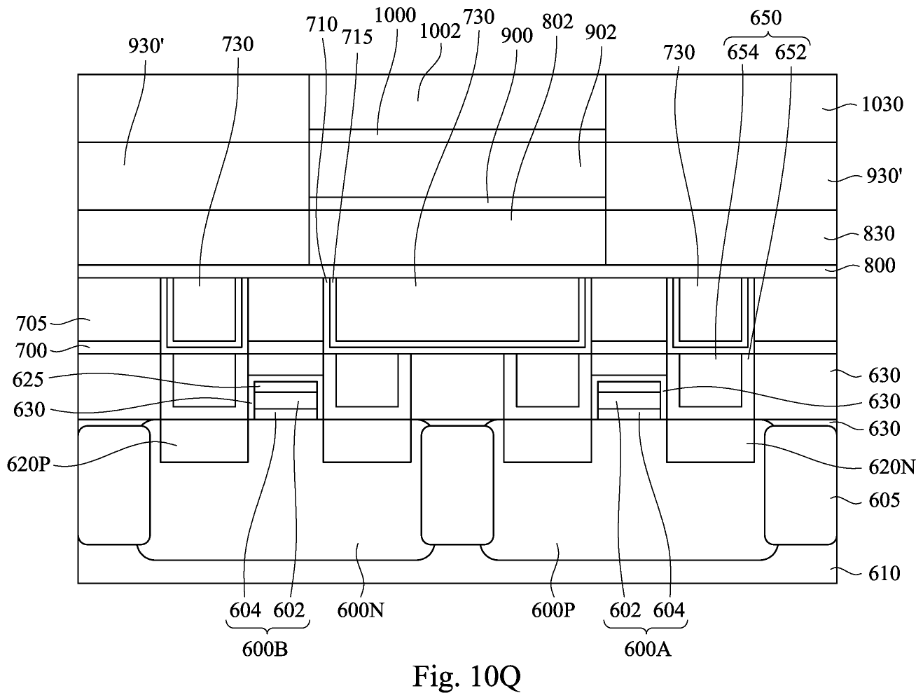

FIGS. 2A-2H illustrate the method M1 in various stages of forming a semiconductor structure in accordance with some embodiments of the present disclosure. The method M1 begins at block S101. Referring to FIG. 2A, in some embodiments of block S101, a substrate W1 is provided. The substrate W1 may be a semiconductor substrate, such as a bulk semiconductor, a semiconductor-on-insulator (SOI) substrate, or the like, which may be doped (e.g., with a p-type or an n-type impurity) or undoped. The substrate W1 may be a wafer, such as a silicon wafer. Generally, a SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate W1 may include silicon; germanium; a compound semiconductor including silicon carbide, gallium arsenide, gallium phosphide, indium phosphide, indium arsenide, and/or indium antimonide; an alloy semiconductor including silicon germanium, gallium arsenide phosphide, aluminum indium arsenide, aluminum gallium arsenide, gallium indium arsenide, gallium indium phosphide, and/or gallium indium arsenide phosphide; combinations thereof; or the like. In some embodiments, the substrate W1 is a semiconductor substrate with transistors and an interconnect structure thereon. The substrate W1 is an intermediate structure of an IC manufacturing process, which can be the substrate illustrated in the embodiments of FIGS. 10A-10Q.

As shown in FIG. 2A, a cleaning process P1 is performed to clean the surface of the substrate W1. In greater detail, the cleaning process P1 is used to remove some contaminants on the metal oxide layer MOX. In some embodiments, the cleaning solvent of the cleaning process P1 is an organic solvent. The organic solvent may have a polar function, such as —OH, —COOH, —CO—, —O—, —COOR, —CN—, —SO—, as non-limiting examples. In various embodiments, the organic solvent may include PGME, PGEE, GBL, CHN, EL, Methanol, Ethanol, Propanol, n-Butanol, Acetone, DMF, Acetonitrile, IPA, THF. Acetic acid, or combinations thereof. In some embodiments, the cleaning process P1 is performed at a time duration in a range from about 5 minutes to about 30 minutes, such as about 5, 6, 7, 8, 9, 10, 11, 12, 13, 14, 15 minutes. Subsequently, another cleaning process is performed to remove a residue of the cleaning solvent of the cleaning process P1 by using, such as deionized water (DI water).

Referring back to FIG. 1, the method M1 then proceeds to block S102 where a bottom electrode layer is deposited on the substrate. With reference to FIGS. 2B and 2C, in some embodiments of block S102, a deposition process P2 (see FIG. 2B) is performed to form a bottom electrode layer 101 (see FIG. 2C) on the surface layer of the substrate W1. In some embodiments, the bottom electrode layer 101 (see FIG. 2C) may include noble metal. In some embodiments, the bottom electrode layer 101 may be made of a conductive material, such as iron (Fe), cobalt (Co), nickel (Ni), copper (Cu), platinum (Pt), palladium (Pd), aluminum (Al), tungsten (W), ruthenium (Ru), Au, Ti, Ta, TiN, TaN, proper alloys thereof, the like, suitable materials, or combinations thereof. In some embodiments, the deposition process P2 (sec FIG. 2B) may be, such as a physical vapor deposition (PVD) process (e.g., e-gun evaporation deposition or thermal evaporation deposition), an atomic layer deposition (ALD), a chemical vapor deposition (CVD), the like, or combinations thereof. In some embodiments, the thermal evaporation deposition may be performed by a deposition system 10 as shown in FIG. 2B, and a metal precursor 360 can be stored in a container 343 of the deposition system 10. In some embodiments, the metal precursor 360 can have a fixed shape in solid form. In some embodiments, the metal precursor 360 may be metal powders that do not have a fixed shape in solid form. A heating device 346 can be controlled by a temperature controller and actuate the metal precursor 360 to form bottom electrode layer 101 on the substrate W1.

Referring back to FIG. 1, the method M1 then proceeds to block S103 where a transition metal layer is deposited on the bottom electrode layer. With reference to FIGS. 2D and 2E, in some embodiments of block S103, a deposition process P3 (see FIG. 2D) is performed to form a transition metal layer 102 (see FIG. 2E) on the bottom electrode layer 101. In some embodiments, the transition metal layer 102 (see FIG. 2E) may include transition metal, such as Mo, W, Pd, Pt, the like, or combinations thereof. In some embodiments, the deposition process P3 (see FIG. 2D) can be, such as a physical vapor deposition (PVD) process (e.g., e-gun evaporation deposition or thermal evaporation deposition process), an atomic layer deposition (ALD), a chemical vapor deposition (CVD), the like, or combinations thereof. In some embodiments, as shown in FIG. 2D, the e-gun evaporation deposition process may be performed by a deposition system 12 as shown in FIG. 2D, and a target material 349, such as transition metal, can be disposed on a support 345 of the deposition system 12. The substrate W1 can be disposed on a holder 347 of the deposition system 12. In some embodiments, in the deposition process P3, an electron beam generated by an electron beam gun 348 of the deposition system 12 can be used to bombard the target material 349. When the target material 349 is melted, and then evaporated to adhere to the bottom electrode layer 101.

In some embodiments, after the formation of the transition metal layer 102 (see FIG. 2E), the transition metal layer 102 may be optionally patterned into a patterned transition metal layer by suitable lithography process and etching process. For example, a mask layer (e.g., silicon nitride layer) is deposited over the transition metal layer 102. and a photoresist layer is coated over the mask layer and patterned by the lithography process. Subsequently, the mask layer is patterned using the patterned photoresist layer as etch mask. Subsequently, the transition metal layer 102 is patterned using the patterned mask layer as etch mask. The patterning may include one or more etching process that etches the material of the transition metal layer 102 at a faster rate than etches the mask layer and etches the bottom electrode layer 101. After the patterning, portions of the transition metal layer 102 exposed by the patterned mask layer are etched away by suitable etching process, and portions of the transition metal layer 102 covered by the patterned mask layer remain after the etching process.

Referring back to FIG. 1, the method M1 then proceeds to block S104 where the transition metal layer is chalcogenized by a plasma-enhanced chemical vapor deposition (PECVD) system, such that a transition metal dichalcogenide (TMDC) layer is formed on the bottom electrode layer as a resistive switching layer of a resistive random access memory (RRAM) device. With reference to FIGS. 2F and 2G, in some embodiments of block S104, the transition metal layer 102 (see FIG. 2E) is chalcogenized by a plasma-enhanced chemical vapor deposition (PECVD) system 14 (see FIG. 2F), such that a TMDC layer 102′ (see FIG. 2G) is formed on the bottom electrode layer 101 as a resistive switching layer.

In some embodiments, the PECVD system 14 can be interchangeably referred to as a microwave plasma-enhanced chemical vapor deposition (MW-PECVD) system. As shown in FIG. 2F, the PECVD system 14 can include a processing chamber 140, a plasma generator 141, a substrate holder 142, a container 143, gas sources 144, 145, a heating device 146, a vacuum pump 147, and a controller 148. The processing chamber 140 can be a processing tube as shown in FIG. 2F. The processing chamber 140 is fabricated from materials such as quartz that provides a non-reactive environment that will sustain plasma generation. In addition to quartz, other materials, including alumina, glass, and the like can be utilized in fabricating the processing chamber 140. The plasma generator 141 is associated with a power supply 122 in order to generate plasma P4 in the processing chamber 140. In some embodiments, the plasma generator 141 is placed over a top of the processing chamber 140, and straddles lateral sides of the processing chamber 140. The plasma generator 141 may not extend to a position directly below the processing chamber 140. The power supply 122 may be a microwave source power that generates microwaves, which may be referred to as electromagnetic waves at frequencies higher than about 300 MHz. In some embodiments, the microwaves may be referred to as an ultra-high frequency (UHF) portion of the RF spectrum, for example in a range from about 2.4 GHz to about 2.5 GHZ, such as at about 2.45 GHZ. As the plasma P4 is microwave plasma generated using the microwaves, the plasma generator 141 may be referred to a microwave plasma reactor. For example, the plasma generator 141 may be a cavity, acting as a resonator, consisting of a metal structure that confines electromagnetic fields in the microwave region of the spectrum. The metal structure is either hollow or filled with dielectric material. The microwaves bounce back and forth between the walls of the cavity. At the cavity's resonant frequencies they reinforce to form standing waves in the cavity. Through the configuration, an energy received from the microwave at a higher position in the processing chamber 140 is greater than an energy received from the microwave at a lower position in the processing chamber 140, such that the plasma P4 is mainly generated in the higher portion of the processing chamber 140.

In some embodiments, a portion 140b of the processing chamber 140 is surrounded by the plasma generator 141, while a portion 140a of the processing chamber 140 fluidly communicated with the portion 140b is not surrounded by the plasma generator 141. Through the configuration, a plasma density in the portion 140b of the processing chamber 140 is higher than a plasma density in the portion 140a of the processing chamber 140. In some alternative embodiments, the plasma generator 141 may surround both portions 140a and 140b of the processing chamber 140, such that a plasma density in the portion 140a may be equal to a plasma density in the portion 140b. In some embodiments, the processing chamber 140 has a gas inlet 1401 and a gas outlet 1400, in which the portions 140a and 140b of the processing chamber 140 is between the gas inlet 1401 and the gas outlet 1400. The portion 140a of the processing chamber 140 may be closer to the gas inlet 1401 than the portion 140b of the processing chamber 140 is.

The substrate holder 142 is placed in the portion 140b of the processing chamber 140, and supports the substrate W1. The substrate holder 142 may be fabricated from materials such as quartz that is inactive to the plasma P4. In addition to quartz, other materials, including alumina, glass, and the like can be utilized in fabricating the substrate holder 142. The substrate holder 142 may be a crucible in some embodiments. As shown in FIG. 2F, the substrate holder 142 may have a trench 142T facing the plasma generator 141. In some embodiments, the substrate holder 142 have a base portion 142B and protruding edges 142P at opposite sidewalls of the base portion 142B, thereby forming the trench 142T. The base portion 142B and protruding edges 142P of the substrate holder 142 may extend along a direction X that the processing chamber 140 extends along. For example, a gas inlet 1401 and a gas outlet 1400 of the processing chamber 140 are at opposite sides of the processing chamber 140 along the direction X. The substrate W1 may be placed between the substrate holder 142 and the plasma generator 141 and supported by the protruding edges 142P. Through the configuration, the substrate W1 may cover at least a portion of the trench 142T.

In some embodiments, a chalcogen precursor 160 is stored in the container 143 placed in the portion 140a of the processing chamber 140. The container 143 may be fabricated from materials such as quartz that is inert to the plasma P4. In addition to quartz, other materials, including alumina, glass, and the like can be utilized in fabricating the container 143. The container 143 may be a crucible in some embodiments. In some embodiments, the chalcogen precursor 160 may be stored in solid form. For example, the chalcogen precursor 160 may be one or more chalcogen pieces that have a fixed shape in solid form. In some embodiments, the chalcogen pieces may be a sulfur (S) piece, selenium (Se) piece, tellurium (Te) piece, the like, or the combination thereof. In some embodiments, the chalcogen precursor 160 may be chalcogen powders that do not have a fixed shape in solid form. For example, the chalcogen powders may be S powders, Se powders, Te powders, the like, or the combination thereof. In still some alternative embodiments, the chalcogen precursor 160 may be stored in liquid form or gas form. For example, the chalcogen precursor 160 may include chalcogen liquids, such as C₂H₆S, SeF₄, or the like, and/or chalcogen gases, such H₂S, SeF₆, CH₄S, WF₆, or the like. In still some alternative embodiments, the chalcogen precursor 160 may include a combination of two or three of chalcogen solids (pieces or powers), chalcogen liquids, and chalcogen gases. The heating device 146, such as a heating tap, may wrap around the portion 140a of the processing chamber 140 and surrounds the chalcogen precursor 160. The heating device 146 may be connected to a temperature controller. Heating of the heating device 146 under control of the temperature controller can melt the chalcogen precursor 160 in solid form and produce the appropriate amount of the chalcogen containing precursor in the vapor phase. For example, in some embodiments where the chalcogen precursor 160 contains sulfur in solid form, which may have a melting point at about 120° C., a temperature of the heating device 146 may be in a range from about 120° C. to about 200° C. If the temperature of the heating device 146 is too low, sulfur may not melt, and little sulfur containing precursor is produced. If the temperature generated by the heating device 146 is too high, sulfur may melt too soon, a sulfur may evaporate and consume too fast, which may result in high cost.

One or more plasma gas sources 144 and 145 are fluidly connected with the gas inlet 140I to provide a gas flow for forming the plasma P4. When the gas sources 144 and 145 provide a gas flow GF for forming plasma P4, the heated chalcogen precursor 160 may add chalcogen gas to the gas flow GF. For example, the gas flow GF containing chalcogen may fill up the portion 140a of the processing chamber 140. The plasma gas sources 144 and 145 may provide Ar and H₂, for example. In some examples, the gas source 144 is a H₂ gas source, and the gas source 145 is an Ar gas source. Mass flow controllers (MFCs) MFC1 and MFC2 or other suitable flow controllers may be utilized to control the flow rate of the gases from the gas sources 144 and 145 to the processing chamber 140. Various valves V11, V12, V21, V22, and V3 can be utilized to control the gas pressure in the processing chamber 140. In some embodiments, the vacuum pump 147 is fluidly connected with the gas outlet 1400 of the processing chamber 140, thereby drawing gas from the processing chamber 140. A backing trap 151 may be utilized in a vacuum line from the gas outlet 1400 to the vacuum pump 147, for preventing back-migration of pumped gas into the processing chamber 140. In some embodiments, in order to monitor the pressure in the processing chamber 140, a pressure gauge 152 can be utilized in the vacuum line from the gas outlet 1400 to the backing trap 151 and the vacuum pump 147. Additional vacuum elements can be utilized as appropriate to the particular application. Additionally, a valve V4 and one or more vacuum control valves V5 can be utilized to control the gas pressure in the processing chamber 140.

In some embodiments, a controller 148 is coupled to the mass flow controllers MFC1 and MFC2, the valves V11, V12, V21, V22, V3-V4, the vacuum control valve V5, the plasma generator 141 and power supply 122, a temperature controller of the heating device 146, and other suitable system components for operating the PECVD system 14. In some implementations, fewer or more components can be coupled to the controller 148. The controller 148 may include a processor 182, a computer readable medium 184, and an input/output (I/O) interface 186. The processor 182 is used to perform calculations related to controlling at least some of the vacuum pressure, gas flow rates, plasma generation, the heating temperature, and other system parameters. A computer readable medium 184 (also referred to as a database or a memory) is coupled to the processor 182 in order to store data used by the processor and other system elements. Using the processor 182, the memory 184, and the I/O interface 186, a user is able to operate the system to form TMDC layer 102′ (see FIG. 2G) as described herein. The processor 182 may include dedicated circuitry. ASICs, combinatorial logic, other programmable processors, combinations thereof, and the like. The processor 182 can execute instructions and data. For example, the processor 182 embodies at least part of the instructions for performing the method in accordance with the present disclosure in software, firmware and/or hardware. The computer readable medium 184 may include a hard disk drive, flash memory, a floppy disk drive along with associated removable media, an optical drive, removable media cartridges, and other like storage media. The computer readable medium 184 can store instructions and data executed by the processor 182.

In FIG. 2F, the substrate W1 is placed over the substrate holder 142. In some embodiments, the substrate W1 can be supported by the protruding edges 142P of the substrate holder 142 without contacting the base portion 142B of the substrate holder 142. The precursor gas flows across the substrate W1 and hence reacts with the transition metal layer 102 (see FIG. 2E) to form TMDC layer 102′ (see FIG. 2G) on the bottom electrode layer 101. This is described in greater detail with reference to FIGS. 2F and 2G, the transition metal layer 102 (see FIG. 2E) is chalcogenized by a micro-wave plasma treatment. In some embodiments, the micro-wave plasma treatment is performed at a frequency in a range from about 2000 to about 3000 MHZ, such as about 2000, 2100, 2200, 2300, 2400, 2450, 2500, 2600, 2700, 2800, 2900, or 3000 MHZ. In some embodiments, the gas flow GF containing chalcogen is directed to the plasma generator 141, and then the plasma generator 141 is used to ionize the gas flow GF to create the plasma P4 around the transition metal layer 102 in the processing chamber 140. In some embodiments, the gas sources 144 and 145 are configured to provide a gas flow containing a mixture of Ar and H₂ to the processing chamber 140. After the gas flow GF passes the portion 140a of the processing chamber 140, the heated chalcogen precursor 160 may add chalcogen gas to the gas flow GF. The plasma generator 141 receives microwaves from the power supply 122, and then the microwaves ionize the gas flow GF with the chalcogen gas and thus generate plasma P4 when microwave energy is high enough. The transition metal layer 102 on the substrate W1 reacts with the chalcogen in the plasma P4, and turns to the TMDC layer 102′. In some embodiments, depending on the chalcogen contained in the gas flow GF, the chalcogenizing process (e.g., turning the transition metal layer 102 into the TMDC layer 102′) may be referred to as sulfurizing process, selenizing process, or the like. TMDCs are a class of materials with the chemical formula MX₂, wherein M is a transition metal clement such as titanium, vanadium, cobalt, nickel, zirconium, molybdenum, technetium, rhodium, palladium, hafnium, tantalum, tungsten, rhenium, iridium, platinum, and X is a chalcogen such as sulfur, selenium, or tellurium. Examples of TMDC may include molybdenum disulfide (MoS₂), tungsten disulfide (WS₂), WSe₂, MoSe₂, molybdenum ditelluride (MoTe₂), WTe₂, the like, or combinations thereof. During the chalcogenizing process, some species may be in-situ doped into the TMDC layer 102′ by fluidly connecting the doping source to the gas inlet 1401.

Once formed, the TMDC layer 102′ (see FIG. 2G) is in a layered structure with one or a plurality of two-dimensional layers of the general form X-M-X, with the chalcogen atoms in two planes separated by a plane of metal atoms. The TMDC layer 102′ may be a mono-layer or may include a few mono-layers, depending on thickness of the transition metal layer 102 (see FIG. 2E). By way of example but not limiting the present disclosure, if the TMDC layer 102′ is in a one-molecule thick, the TMDC layer 102′ may include transition metal atoms forming a layer in a middle region thereof and chalcogen atoms forming a first layer over the layer of transition metal atoms and a second layer underlying the layer of transition metal atoms. The transition metal atoms may be W atoms or Mo atoms, while the chalcogen atoms may be S atoms, Se atoms, or Te atoms. In the example of the TMDC layer 102′ is in a one-molecule thick, each of the transition metal atoms is bonded (e.g., by covalent bonds) to six chalcogen atoms, and each of the chalcogen atoms is bonded (e.g. by covalent bonds) to three transition metal atoms. Throughout the description, the illustrated cross-bonded layers including one layer of transition metal atoms and two layers of chalcogen atoms in combination are referred to as a mono-layer of the TMDC layer 102′. In some further embodiments, by depositing the transition metal layer 102 (referring to FIG. 2E) with suitable thicknesses and etching the transition metal layer 102 (referring to FIG. 2E) with desired patterns, the resultant TMDC layer 102′ may be formed with suitable thicknesses and desired patterns.

In some embodiments, since the microwave plasma is reaction trigger, the plasma can be formed intensively with a high energy in the desired region, such that a transition metal layer 102 (see FIG. 2E) can be turned into a TMDC layer 102′ (see FIG. 2G) without heating the substrate W1 (e.g., using a heating device in contact with the substrate W1 to directly heat the substrate W1). Through the configuration, the TMDC layer 102′ is synthesized at a low temperature. For example, a temperature of the processing chamber 140 (see FIG. 2F) can be controlled below about 400° C., which may reduce the thermal budget. Thermal budget may be referred to as total amount of thermal energy transferred to the wafer during the given elevated temperature operation, and low thermal budget is desired in IC manufacturing to prevent dopant redistribution. Also, in some embodiments of the present disclosure, the TMDC layer 102′ (see FIG. 2G) is formed without heating the substrate W1 (e.g., using a heating device in contact with the substrate W1 to directly heat the substrate W1), thereby the process for heating and cooling the substrate W1 is not required, which in turn will lead to short process time.

In some embodiments, during the plasma treatment on the transition metal layer 102 (see FIG. 2E), the operating power of the power supply 122 (see FIG. 2F) may be in a range from about 10 W to about 40 W, such as about 10, 15, 20, 25, 30, 35, or 40 W. If the power is lower than about 10 W, it is hard to form plasma. If the power is higher than about 40 W, the substrate or a peripheral region of the substrate may be damaged by plasma. In some embodiments, during the plasma treatment on the transition metal layer 102, a flow rate of the gas flow GF provided by the gas sources 144 and 145 is in a range from about 1 standard cubic centimeter per minute (sccm) to about 10 sccm, such as about 1, 2, 3, 4, 5, 6, 7, 8, 9, or 10 sccm. The gas flow GF may include a reactive gas mixture of H₂, Ar, and H₂S. If the flow rate of the gas flow GF is lower than about 1 sccm, it is hard to form plasma. If the flow rate of the gas flow GF is greater than about 10 sccm, the chalcogen gas (e.g., H₂S) may move too fast to react with metal film, and the pressure may be too high to form plasma. In some embodiments, during the plasma treatment on the transition metal layer 102, the process pressure of the processing chamber 140, for example, monitored by the pressure gauge 152, is in a range from several mTorrs to hundreds of mTorrs. For example, the process pressure of the processing chamber 140 may be in a range from about 1×10⁻¹ to about 1×10⁻² torr. If the pressure is higher than about 1×10⁻¹ torr, the ionization efficiency is low, and it may not be easy to form plasma. If the pressure is lower than about 1×10⁻², the voltage to break down the gas is high, and therefore it may not be easy to form plasma. In some embodiments, a time duration for performing the plasma treatment on the transition metal layer 102 is in a range from about 1 minute to about 30 minutes, such as about 1, 2, 3, 4, 5, 6, 7, 8, 9, 10, 11, 12, 13, 14, 15, 16, 17, 18, 19, 20, 21, 22, 23, 24, 25, 26, 27, 28, 29, or 30 minutes. mminutes. If the time duration is less about 1 minute, the chalcogenizing reaction may be incomplete, which may result in non-uniform chalcogenized metal layers. If the time duration is greater than about 15 minutes, long-time exposure to plasma may result in rough surface damage, and it may unnecessarily increase process time. In some embodiments, a time duration for performing the plasma treatment on the transition metal layer 102 can be less than about 10 minutes.

Referring back to FIG. 1, the method M1 then proceeds to block S105 where a top electrode layer is deposited on the TMDC layer. With reference to FIG. 2H, in some embodiments of block S105, the substrate W1 is moved out from the processing chamber 140 of the deposition system 14 (see FIG. 2F). The top electrode layer 103 is deposited over the TMDC layer 102′. In some embodiments, the top electrode layer 103 may include noble metal. In some embodiments, the top electrode layer 103 may be made of a conductive material, such as iron (Fe), cobalt (Co), nickel (Ni), copper (Cu), platinum (Pt), palladium (Pd), aluminum (Al), tungsten (W), ruthenium (Ru), Au, Ti, Ta, TiN, TaN, proper alloys thereof, the like, suitable materials, or combinations thereof. In some embodiments, the top electrode layer 103 may be formed by a deposition process P5, such as a physical vapor deposition (PVD) process (e.g., e-gun evaporation deposition or thermal evaporation deposition), an atomic layer deposition (ALD), a chemical vapor deposition (CVD), the like, or combinations thereof. In some embodiments, the thermal evaporation deposition may be performed by the deposition system 10 as shown in FIG. 2B. In some embodiments, the top electrode layer 103 may be made of a different material than the bottom electrode layer 101. In some embodiments, the top electrode layer 103 may be made of a same material as the bottom electrode layer 101.

In some embodiments, after the deposition of the top electrode layer 103, the top electrode layer 103 may be optionally patterned into a patterned metal layer by suitable lithography process and etching process. For example, a mask layer (e.g., silicon nitride layer) is deposited over the top electrode layer 103, and a photoresist layer is coated over the mask layer and patterned by the lithography process. Subsequently, the mask layer is patterned using the patterned photoresist layer as etch mask. Then, the top electrode layer 103 is patterned using the patterned mask layer as etch mask. The patterning may include one or more etching process that etches the material of the top electrode layer 103 at a faster rate than etches the mask layer and etches the TMDC layer 102′ and the bottom electrode layer 101. After the patterning, portions of the metal layer exposed by the patterned mask layer are etched away by suitable etching process, and portions of the metal layer covered by the patterned mask layer remain after the etching process. In some embodiments, the top electrode layer 103 may be patterned into a metal dot array 130A. The metal dot array 103A includes several metal dots 103D arranged in a predetermined pattern and is disposed on a surface of the underlying TMDC layer 102′. In some embodiments, the patterning generates the metal dot array 103A having a separation S1 between two adjacent metal dots 103D.

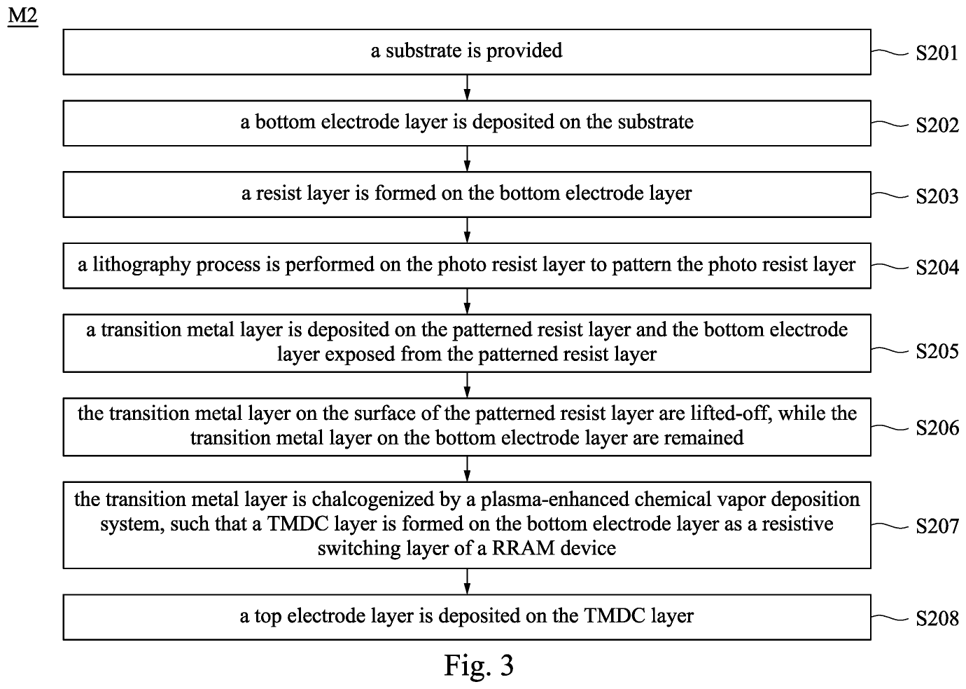

Referring now to FIG. 3, illustrated is a flowchart of an exemplary method M2 for fabrication of a semiconductor structure in accordance with some embodiments. The method M2 includes a relevant part of the entire manufacturing process. It is understood that additional operations may be provided before, during, and after the operations shown by FIG. 3, and some of the operations described below can be replaced or eliminated for additional embodiments of the method. The order of the operations/processes may be interchangeable. The method M2 includes fabrication of a semiconductor structure. However, the fabrication of the semiconductor structure is merely an example for describing the manufacturing process according to some embodiments of the present disclosure.

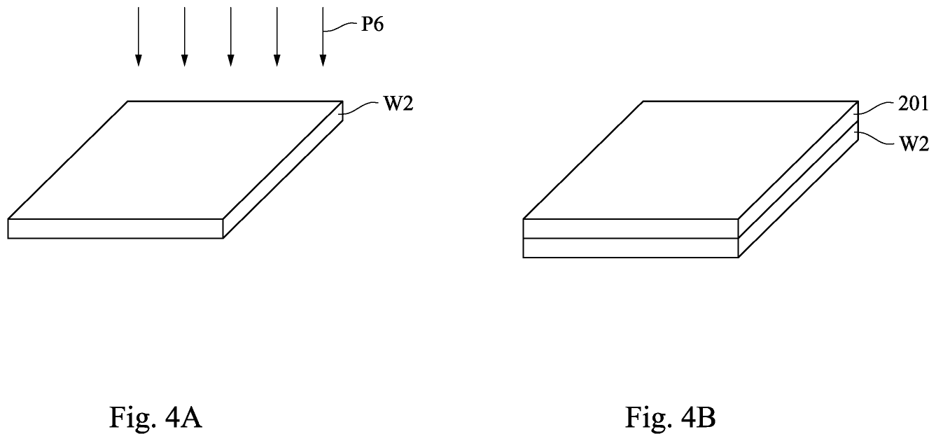

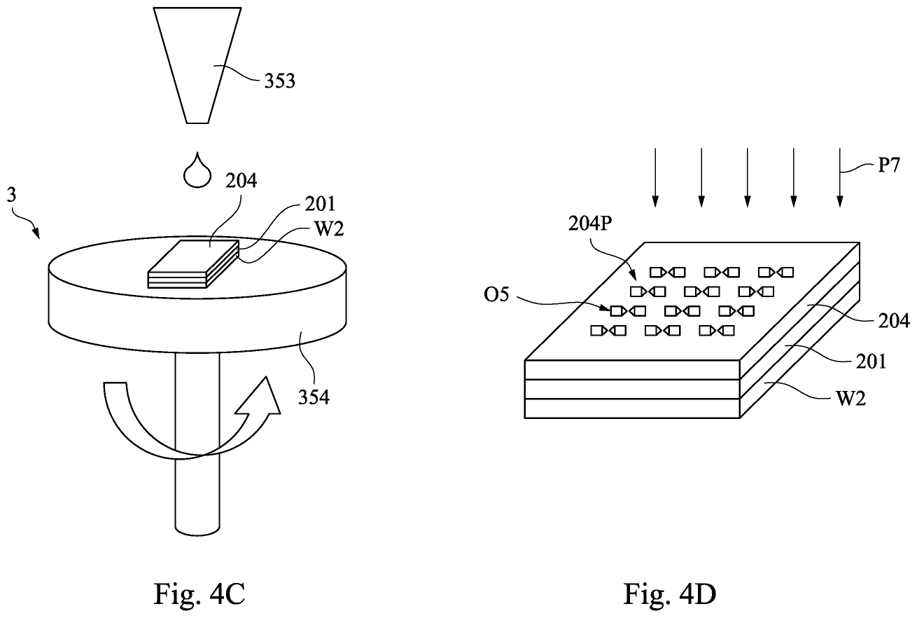

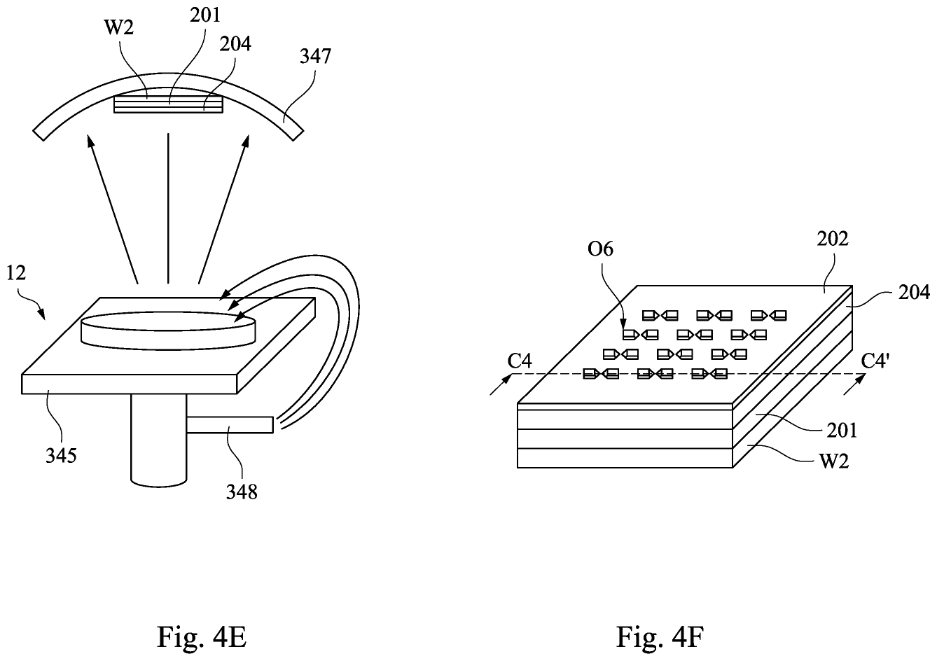

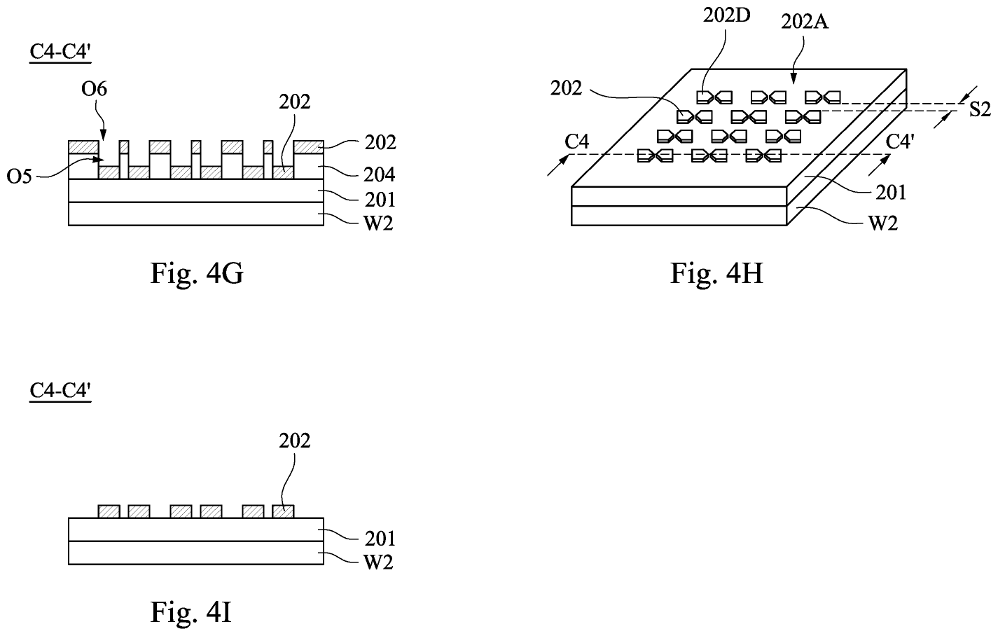

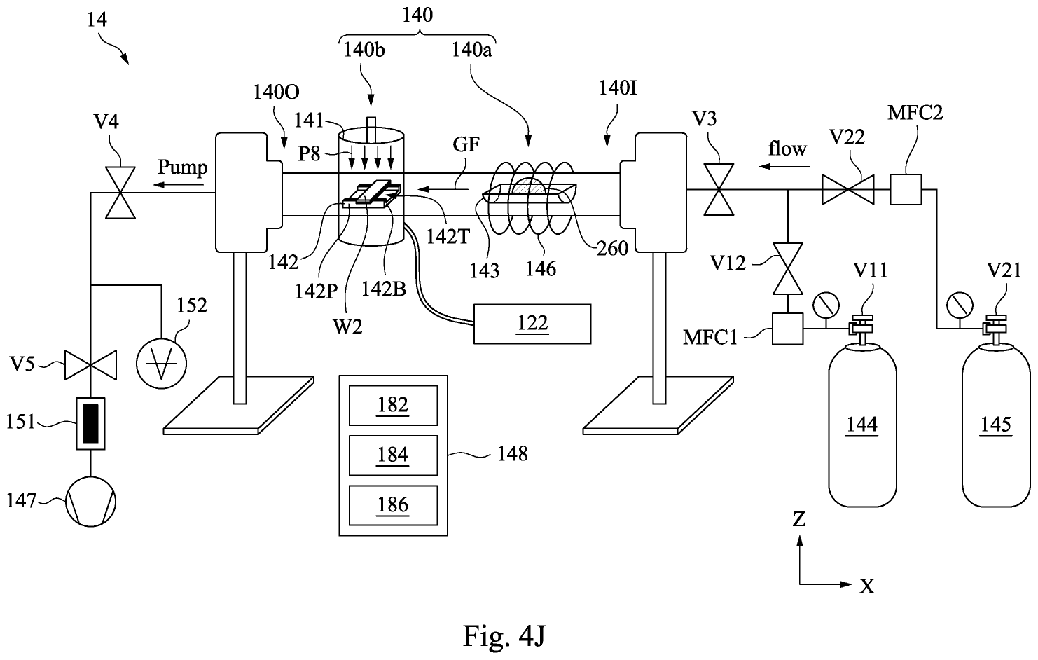

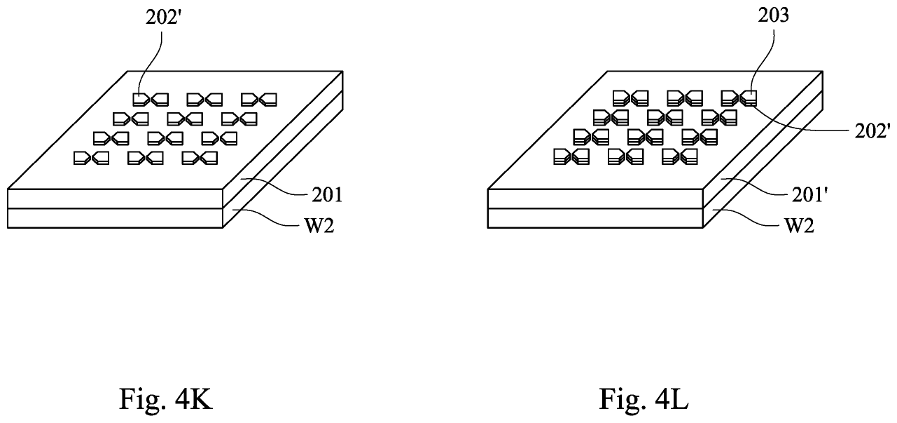

FIGS. 4A-4H illustrate the method M2 in various stages of forming a semiconductor structure in accordance with some embodiments of the present disclosure. The method M2 begins at block S201. Referring to FIG. 4A, in some embodiments of block S201, a substrate W2 is provided. The substrate W2 is similar to the substrate W1 as shown in FIGS. 2A-2H, and thus relevant details will not be repeated for brevity. As shown in FIG. 4A, a cleaning process P6 is performed to clean the surface of the substrate W2. In greater detail, the cleaning process P6 is used to remove some contaminants on the metal oxide layer MOX. In some embodiments, the cleaning solvent of the cleaning process P6 is an organic solvent. The organic solvent may have a polar function, such as —OH, —COOH, —CO—, —O—, —COOR, —CN—, —SO—, as non-limiting examples. In various embodiments, the organic solvent may include PGME, PGEE, GBL, CHN, EL, Methanol, Ethanol, Propanol, n-Butanol, Acetone, DMF, Acetonitrile, IPA, THF, Acetic acid, or combinations thereof. In some embodiments, the cleaning process P1 is performed at a time duration in a range from about 5 minutes to about 15 minutes, such as about 5, 6, 7, 8, 9, 10, 11, 12, 13, 14, or 15 minutes. Subsequently, another cleaning process is performed to remove a residue of the cleaning solvent of the cleaning process P6 by using, such as deionized water (DI water).

Referring back to FIG. 3, the method M2 then proceeds to block S202 where a bottom electrode layer is deposited on the substrate. With reference to FIG. 4B, in some embodiments of block S202, the bottom electrode layer 201 is deposited over the surface layer of the substrate W2. In some embodiments, material and manufacturing method of the bottom electrode layer 201 is substantially the same as that of the substrate 101 as shown in FIGS. 2B-2H, and the related detailed descriptions may refer to the foregoing paragraphs, and are not described again herein.

Referring back to FIG. 3, the method M2 then proceeds to block S203 where a resist layer is formed on the bottom electrode layer. With reference to FIG. 4C, in some embodiments of block S203, a resist layer 204 may be coated on the bottom electrode layer 201 using a spin-on coating process through a coating apparatus 3. In some embodiments, the resist layer 204 may be a deep UV photoresist. The resist layer 204 may be either a positive tone or a negative tone material, which is then exposed and developed in an aqueous base solution to form a pattern which will be transferred to the overlying target layer (e.g. transition metal layer 202 as shown in FIG. 4F) for defining the pattern thereon in subsequent processes. Specifically, in the spin-on coating process, a liquid material of the resist layer 204 is dispensed on a substantial center region of substrate W2 by a dispensing nozzle 353, and the wafer stage 354 (see FIG. 4C) simultaneously rotates the substrate W2 at a rotational speed. In some embodiments, the dispensing nozzle 353 scans across the surface of the substrate W2 during the coating. It is noted that the number of layer in the resist layer 204 is exemplary. In some embodiments, the resist layer 204 may be a multi-layered structure. Subsequently, a baking process can be performed on the resist layer 204 at an elevated temperature to evaporate the solvent in the resist layer 204 for a time duration sufficient to cure and dry the resist layer 204.

Referring back to FIG. 3, the method M2 then proceeds to block S204 where a lithography process is performed on the photo resist layer to pattern the photo resist layer. With reference to FIG. 4D, in some embodiments of block S204, the resist layer 204 is exposed to a radiation in a lithography system (not shown) to form a pattern 204P having openings O5. An exposing process P7 is performed on the resist layer 204 in a lithography system. In some embodiments, the radiation generated by the exposing process P7 may be an I-line (365 nm), a DUV radiation such as KrF excimer laser (248 nm) or ArF excimer laser (193 nm), a EUV radiation (e.g., 13.8 nm), an e-beam, an x-ray, an ion beam, or other suitable radiations. The exposure may be performed in air, in a liquid (immersion lithography), or in a vacuum (e.g., for EUV lithography and e-beam lithography). In some embodiments, the radiation generated by the exposing process P7 may be patterned with a photomask or reticle (not shown), such as a transmissive mask or a reflective mask, which may include resolution enhancement techniques such as phase-shifting and/or optical proximity correction (OPC). In some embodiments, the radiation generated by the exposing process P7 may be directly modulated with a predefined pattern without using a photomask (maskless lithography). In some embodiments, the radiation generated by the exposing process P7 may irradiate portions of the resist layer according to a pattern, either with a mask or maskless. In some embodiments, the resist layer 204 may be a positive resist and the irradiated portions become soluble in a developing chemical. In some embodiments, the resist layer 204 may be a negative resist and the unexposed portions become insoluble in a developing chemical.

Subsequently, a post-baking process is performed on the resist layer 204 in order to assist in the generating, dispersing, and reacting of the acid/base/free radical generated from the impingement of the energy upon the photoactive compounds in the resist layer 204 during the exposure in the radiation generated by the exposing process P7. Such assistance can help to create or enhance chemical reactions which generate chemical differences and different polarities between the irradiated portions and the unexposed portions within the resist layer 204. These chemical differences results in differences in the solubility between the irradiated portions and the unexposed portions of the resist layer 204. Subsequently, a developing process is performed to the exposed resist layer 204. The developing process introduces a developing chemical to the irradiated portions of the resist layer 204, and then the irradiated portions can be removed by the developing chemical and results in a patterned resist layer 204 to expose the substrate W1. In some embodiments, the developing chemical may be dissolved in a solvent. In one example. the developing chemical may be a positive tone developing chamber, e.g., containing tetramethylammonium hydroxide (TMAH) dissolved in an aqueous solution. In some embodiments, the developing chemical may be a negative tone developing chamber, e.g., containing n-Butyl Acetate (nBA) dissolved in an organic solvent. In some embodiments, the developing chemical can be interchangeably referred to as a developer.

Referring back to FIG. 3, the method M2 then proceeds to block S205 where a transition metal layer is deposited on the patterned resist layer and the bottom electrode layer exposed from the patterned resist layer. With reference to FIGS. 4E-4G, in some embodiments of block S205, a transition metal layer 202 is deposited on the patterned resist layer 204 and the bottom electrode layer 201 exposed from the patterned resist layer 204. In some embodiments, material and manufacturing method of the transition metal layer 202 is substantially the same as that of the transition metal layer 102 as shown in FIGS. 2E-2H, and the related detailed descriptions may refer to the foregoing paragraphs, and are not described again herein. In some embodiments, the transition metal layer 202 formed on the patterned resist layer 204 can have openings O6 (see FIG. 4F) therein, and the openings O6 overlaps the underlying openings O5 (see FIG. 4G) in the resist layer 204.

Referring back to FIG. 3, the method M2 then proceeds to block S206 where the transition metal layer on the surface of the patterned resist layer are lifted-off, while the transition metal layer on the bottom electrode layer are remained. With reference to FIGS. 4H and 4I, in some embodiments of block S206, the transition metal layer 202 (see FIGS. 4F and 4G) on the surface of the patterned resist layer 204 are lifted-off, while the transition metal layer 202 on the bottom electrode layer 201 are remained. This is described in greater detail, the substrate W2 can be immersed into a tank of appropriate solvent that will react with the patterned resist layer 204. The patterned resist layer 204 swells, dissolves, and lifts off the transition metal layer 202 (see FIGS. 4F and 4G) on the surface of the resist layer 204, leaving portions of the transition metal layer 202 over the bottom electrode layer 201. The resulting structure is shown in FIGS. 4H and 4I. In some embodiments, any residual resist 204 is optionally cleaned by another solvent or by appropriate plasma chemistry to control defect density. Examples of suitable solvents include xylene and methyl iso-butyl ketone (MIBK). In some embodiments, this process be carded out in an ultrasonic bath with agitation to enhance the lift-off of undesirable metalization. In some embodiments, the transition metal layer 202 may be patterned into a metal dot array 202A. The metal dot array 202A includes several metal dots 202D arranged in a predetermined pattern and is disposed on a surface of the underlying bottom electrode layer 201. In some embodiments, the patterning generates the metal dot array 202A having a separation S2 between two adjacent metal dots 202D.

Referring back to FIG. 3, the method M2 then proceeds to block S207 where the transition metal layer is chalcogenized by a PECVD system, such that a TMDC layer is formed on the bottom electrode layer as a resistive switching layer of a RRAM device. With reference to FIGS. 4J and 4K, in some embodiments of block S207, the transition metal layer 202 (see FIGS. 4H and 4I) is chalcogenized by the PECVD system 14 (see FIG. 4J), such that a TMDC layer 202′ (see FIG. 4K) is formed on the bottom electrode layer 201 as a resistive switching layer of a resistive random access memory (RRAM) device.

In FIG. 4J, the substrate W2 is placed over the substrate holder 142. In some embodiments, the substrate W2 can be supported by the protruding edges 142P of the substrate holder 142 without contacting the base portion 142B of the substrate holder 142. The precursor gas flows across the substrate W2 and hence reacts with the transition metal layer 202 (see FIGS. 4H and 4I) to form TMDC layer 202′ (scc FIG. 4K) on the bottom electrode layer 201. This is described in greater detail with reference to FIGS. 4J and 4K, the transition metal layer 202 (see FIGS. 4H and 4I) is chalcogenized by a micro-wave plasma treatment. In some embodiments, the micro-wave plasma treatment is performed at a frequency in a range from about 2000 to about 3000 MHz, such as about 2000, 2100, 2200, 2300, 2400, 2450, 2500, 2600, 2700, 2800, 2900, or 3000 MHz. In some embodiments, the gas flow GF containing chalcogen is directed to the plasma generator 141, and then the plasma generator 141 is used to ionize the gas flow GF to create the plasma P4 around the transition metal layer 202 in the processing chamber 140. In some embodiments, the gas sources 144 and 145 are configured to provide a gas flow containing a mixture of Ar and H₂ to the processing chamber 140. After the gas flow GF passes the portion 140a of the processing chamber 140, a heated chalcogen precursor 260 stored in the container 143 may add chalcogen gas to the gas flow GF. In some embodiments, the chalcogen precursor 260 is similar to the chalcogen precursor 160 as shown in FIG. 2F. The plasma generator 141 receives microwaves from the power supply 122, and then the microwaves ionize the gas flow GF with the chalcogen gas and thus generate plasma P8 when microwave energy is high enough. The transition metal layer 202 on the substrate W2 reacts with the chalcogen in the plasma P8, and turns to the TMDC layer 202′. In some embodiments, depending on the chalcogen contained in the gas flow GF, the chalcogenizing process (e.g., turning the transition metal layer 202 into the TMDC layer 202′) may be referred to as sulfurizing process, selenizing process, or the like. TMDCs are a class of materials with the chemical formula MX₂, wherein M is a transition metal element such as titanium, vanadium, cobalt, nickel, zirconium, molybdenum, technetium, rhodium, palladium, hafnium, tantalum, tungsten, rhenium, iridium, platinum, and X is a chalcogen such as sulfur, selenium, or tellurium. Examples of TMDC may include MoS₂, WS₂, WSe₂, MoSe₂, MoTe₂, WTe₂, the like, or combinations thereof. During the chalcogenizing process, some species may be in-situ doped into the TMDC layer 202′ by fluidly connecting the doping source to the gas inlet 140I.

Once formed, the TMDC layer 202′ (see FIG. 4K) is in a layered structure with one or a plurality of two-dimensional layers of the general form X-M-X, with the chalcogen atoms in two planes separated by a plane of metal atoms. The TMDC layer 202′ may be a mono-layer or may include a few mono-layers, depending on thickness of the transition metal layer 202 (see FIGS. 4H and 4I). By way of example but not limiting the present disclosure, if the TMDC layer 202′ is in a one-molecule thick, the TMDC layer 202′ may include transition metal atoms forming a layer in a middle region thereof and chalcogen atoms forming a first layer over the layer of transition metal atoms and a second layer underlying the layer of transition metal atoms. The transition metal atoms may be W atoms or Mo atoms, while the chalcogen atoms may be S atoms, Se atoms, or Te atoms. In the example of the TMDC layer 202′ is in a one-molecule thick, each of the transition metal atoms is bonded (e.g., by covalent bonds) to six chalcogen atoms, and each of the chalcogen atoms is bonded (e.g. by covalent bonds) to three transition metal atoms. Throughout the description, the illustrated cross-bonded layers including one layer of transition metal atoms and two layers of chalcogen atoms in combination are referred to as a mono-layer of the TMDC layer 202′. In some further embodiments, by depositing the transition metal layer 202 (referring to FIGS. 4H and 4I) with suitable thicknesses and etching the transition metal layer 202 (referring to FIGS. 4H and 4I) with desired patterns, the resultant TMDC layer 202′ may be formed with suitable thicknesses and desired patterns.

In some embodiments, since the microwave plasma is reaction trigger, the plasma can be formed intensively with a high energy in the desired region, such that a transition metal layer 202 (see FIGS. 4H and 4I) can be turned into a TMDC layer 202′ (see FIG. 4K) without heating the substrate W2 (e.g., using a heating device in contact with the substrate W2 to directly heat the substrate W2). Through the configuration, the TMDC layer 202′ is synthesized at a low temperature. For example, a temperature of the processing chamber 140 (see FIG. 4J) can be controlled below about 400° C., which may reduce the thermal budget. Thermal budget may be referred to as total amount of thermal energy transferred to the wafer during the given elevated temperature operation, and low thermal budget is desired in IC manufacturing to prevent dopant redistribution. Also, in some embodiments of the present disclosure, the TMDC layer 202′ (see FIG. 4K) is formed without heating the substrate W2 (e.g., using a heating device in contact with the substrate W2 to directly heat the substrate W2), thereby the process for heating and cooling the substrate W2 is not required, which in turn will lead to short process time.

In some embodiments, during the plasma treatment on the transition metal layer 202 (sec FIGS. 4H and 4I), the operating power of the power supply 122 (see FIG. 4J) may be in a range from about 10 W to about 40 W, such as about 10, 15, 20, 25, 30, 35, or 40 W. If the power is lower than about 20 W, it is hard to form plasma. If the power is higher than about 100 W, the substrate or a peripheral region of the substrate may be damaged by plasma. In some embodiments, during the plasma treatment on the transition metal layer 202, a flow rate of the gas flow GF provided by the gas sources 144 and 145 is in a range from about 1 standard cubic centimeter per minute (sccm) to about 10 sccm, such as about 1, 2, 3, 4, 5, 6, 7, 8, 9, or 10 sccm. The gas flow GF may include a reactive gas mixture of H₂. Ar, and H₂S. If the flow rate of the gas flow GF is lower than about 1 sccm, it is hard to form plasma. If the flow rate of the gas flow GF is greater than about 10 sccm, the chalcogen gas (e.g., H₂S) may move too fast to react with metal film, and the pressure may be too high to form plasma. In some embodiments, during the plasma treatment on the transition metal layer 202, the process pressure of the processing chamber 140, for example, monitored by the pressure gauge 152, is in a range from several mTorrs to hundreds of mTorrs. For example, the process pressure of the processing chamber 140 may be in a range from about 1×10⁻¹ to about 1×10⁻² torr. If the pressure is higher than about 1×10⁻¹ torr, the ionization efficiency is low, and it may not be easy to form plasma. If the pressure is lower than about 1×10⁻², the voltage to break down the gas is high, and therefore it may not be easy to form plasma. In some embodiments, a time duration for performing the plasma treatment on the transition metal layer 202 is in a range from about 1 minute to about 30 minutes, such as about 1, 2, 3, 4, 5, 6, 7, 8, 9, 10, 11, 12, 13, 14, 15, 16, 17, 18, 19, 20, 21, 22, 23, 24, 25, 26, 27, 28, 29, or 30 minutes. If the time duration is less about 1 minute, the chalcogenizing reaction may be incomplete, which may result in non-uniform chalcogenized metal layers. If the time duration is greater than about 15 minutes, long-time exposure to plasma may result in rough surface damage, and it may unnecessarily increase process time. In some embodiments, a time duration for performing the plasma treatment on the transition metal layer 102 can be less than about 10 minutes.

Referring back to FIG. 3, the method M2 then proceeds to block S208 where a top electrode layer is deposited on the TMDC layer. With reference to FIG. 4L, in some embodiments of block S208, the substrate W2 is moved out from the processing chamber 140 of the deposition system 14. The top electrode layer 203 is deposited over the TMDC layer 202′. In some embodiments, material and manufacturing method of the top electrode layer 203 is substantially the same as that of the top electrode layer 103 as shown in FIG. 2H, and the related detailed descriptions may refer to the foregoing paragraphs, and are not described again herein. In some embodiments, after the deposition of the top electrode layer 203, the top electrode layer 203 may be optionally patterned into a patterned metal layer by suitable lithography process and etching process. For example, a mask layer (e.g., silicon nitride layer) is deposited over the top electrode layer 203, and a photoresist layer is coated over the mask layer and patterned by the lithography process. Subsequently, the mask layer is patterned using the patterned photoresist layer as etch mask. Then, the top electrode layer 203 is patterned using the patterned mask layer as etch mask. The patterning may include one or more etching process that etches the material of the top electrode layer 203 at a faster rate than etches the mask layer and etches the bottom electrode layer 201. After the patterning, portions of the metal layer exposed by the patterned mask layer are etched away by suitable etching process, and portions of the metal layer covered by the patterned mask layer remain after the etching process. In some embodiments, the top electrode layer 203 may be made of a different material than the bottom electrode layer 201. In some embodiments, the top electrode layer 203 may be made of a same material as the bottom electrode layer 201.

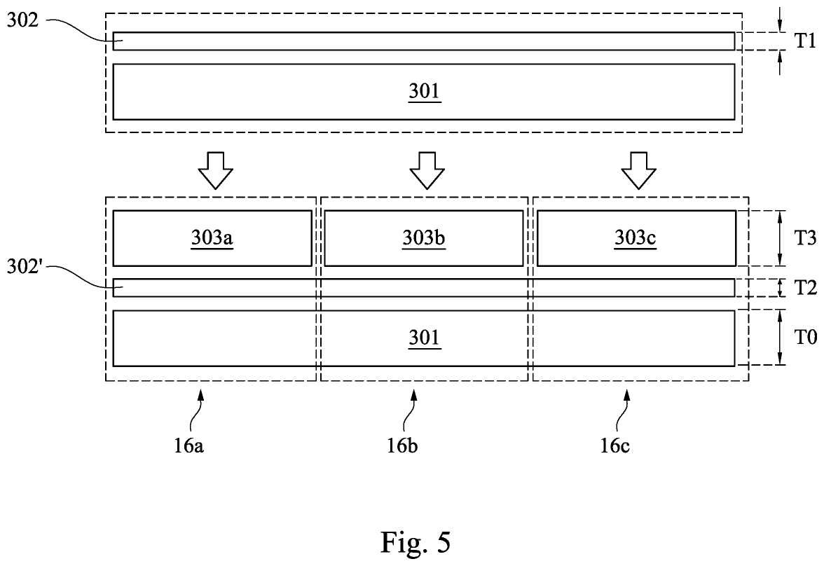

Reference is made to FIG. 5. FIG. 5 is a schematic diagram illustrating a method in various stages of forming a semiconductor structure in accordance with some embodiments of the present disclosure. The semiconductor structure can be provided to include a noble metal 301 (e.g., Aurum (Au)) as a bottom electrode of a RRAM device, and a transition metal 302 over the noble metal 301. In some embodiments, the noble metal 301 may have a thickness in a range from about 10 nm to about 100 nm, by way of example but not limiting the present disclosure. Subsequently, the transition metal is chalcogenized by the PECVD system 14 as shown in FIG. 2F, such that a TMDC layer 302′ is formed on the noble metal 301 as a resistive switching layer of a RRAM device. In some embodiments, the transition metal may be sulfide by micro-wave plasma generated by the PECVD system 14 to form a transition metal sulfide layer. In some embodiments, the TMDC layer 302′ has a thicker thickness T2 than a thickness T1 of the transition metal 302. By way of example but not limiting the present disclosure, the thickness Tl of the transition metal 302 may be in a range from about 0.5 nm to about 2 nm, and the thickness T2 of the TMDC layer 302′ may be in a range from about 2 nm to about 10 nm. Subsequently, a top electrode material 303a, 303b, or 303c may be formed on the TMDC layer 302′ as a top electrode of the RRAM device, such that a RRAM device 16a, 16b, or 16c is formed. In some embodiments, the top electrode material 303a, 303b, or 303c may be made of a same material as the noble metal 301. In some embodiments, the top electrode material 303a, 303b, or 303c may be made of a different material than the noble metal 301. The top electrode material 303a, 303b, or 303c may have a thickness T3 the same as a thickness TO of the noble metal 301. In some embodiments, the thickness T3 of the top electrode material 303a, 303b, or 303c may be different than the thickness T0 of the noble metal 301. By way of example but not limiting the present disclosure, the thickness T3 of the top electrode material 303a, 303b, or 303c may be in a range from about 10 nm to about 100 nm. In some embodiments, the top electrode material 303a, 303b, or 303c may be formed by an e-gun evaporation deposition process, and thus can be interchangeably referred to as a evaporated top electrode.

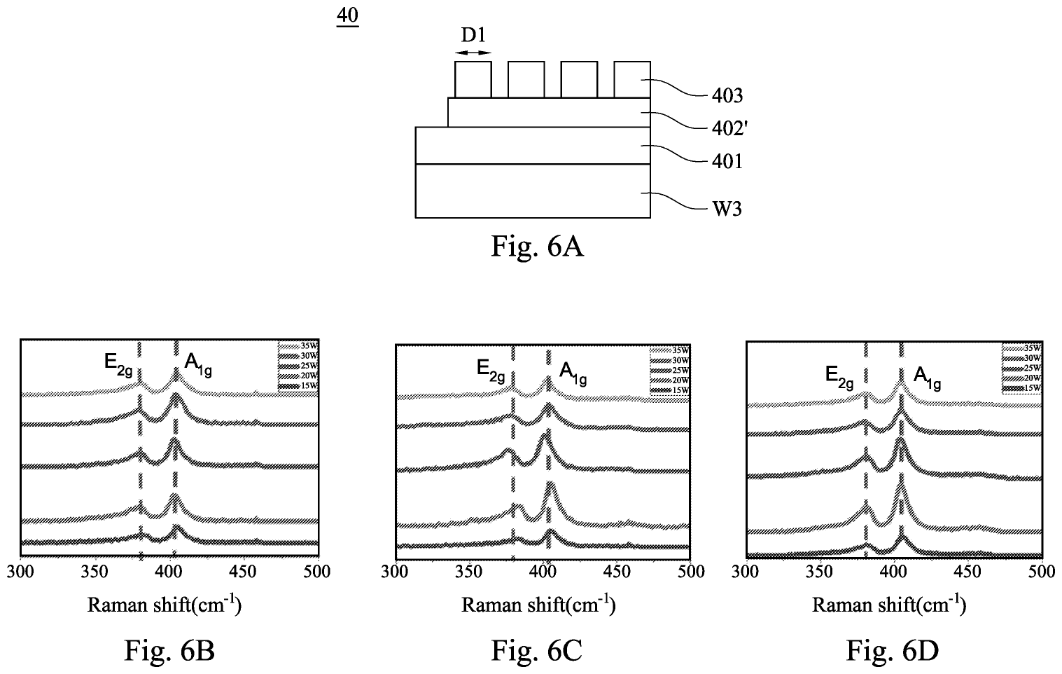

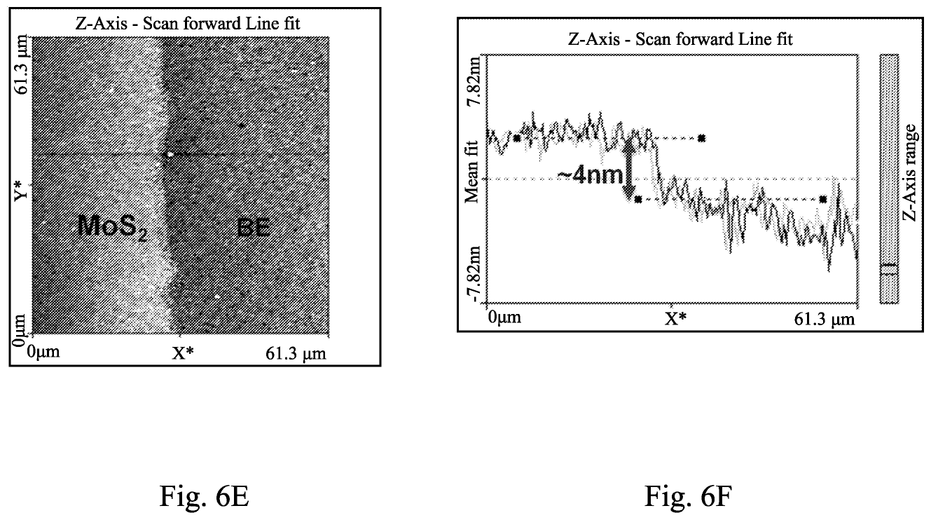

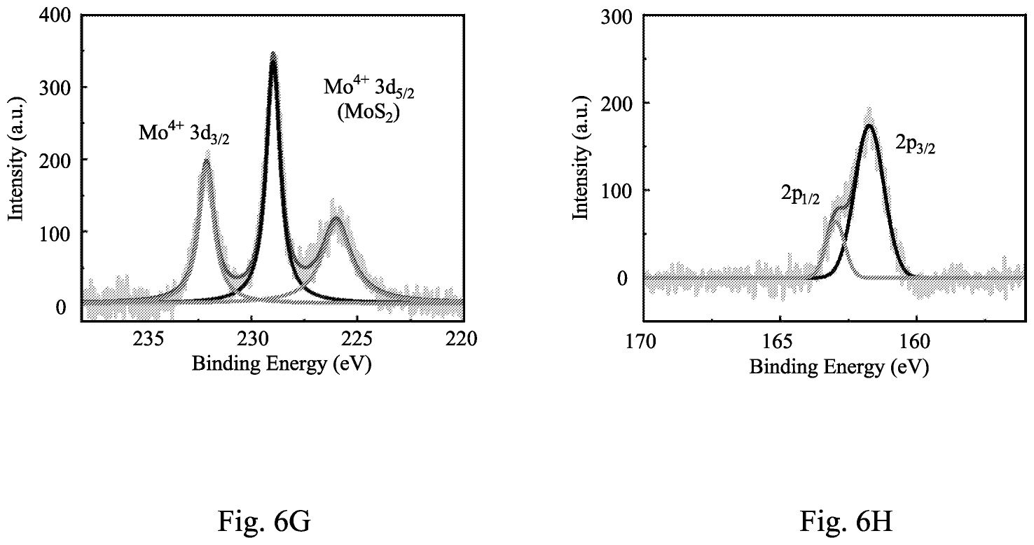

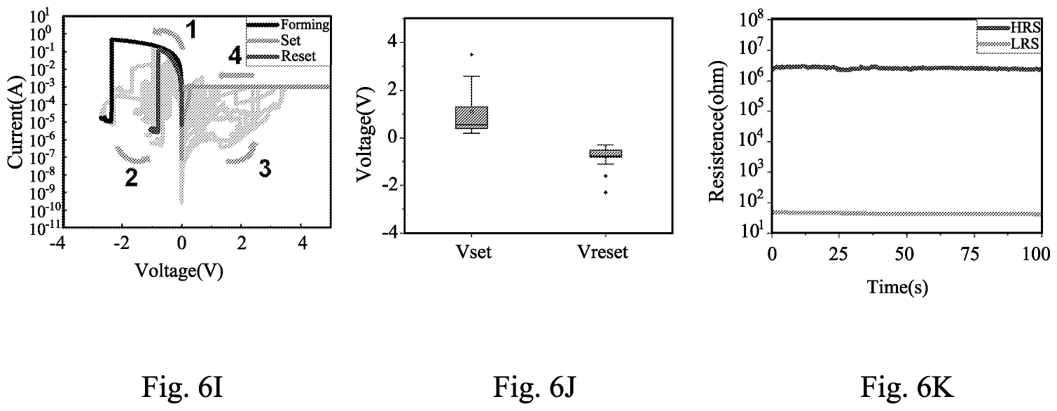

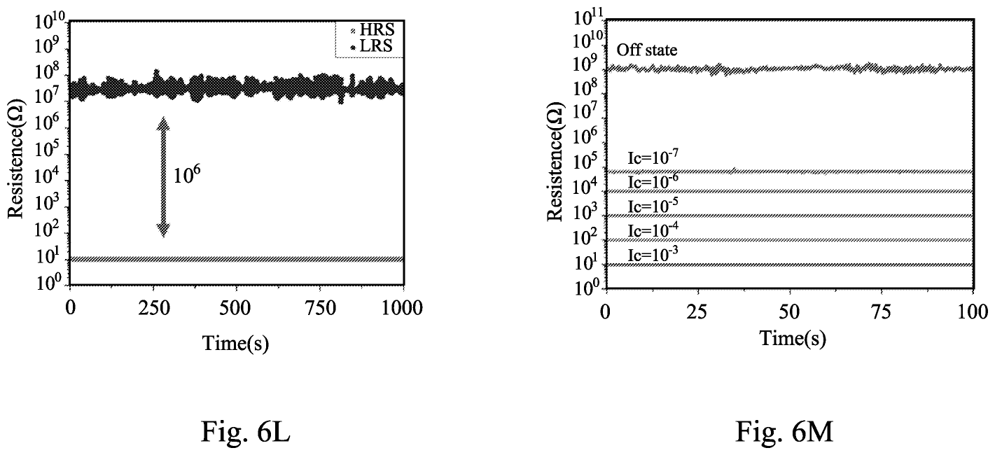

Reference is made to FIGS. 6A-6M. FIG. 6A is a schematic diagram of a semiconductor structure in accordance with some embodiments of the present disclosure. FIGS. 6B-6M illustrate experimental results of the semiconductor structure of FIG. 6A. As shown in FIG. 6A, a RRAM device 40 is provided. The RRAM device 40 is formed by a fabrication process as shown in FIGS. 2A-2H. In some embodiments, the RRAM device 40 may include a substrate W3, a bottom electrode layer 401, a top electrode layer 403, and a resistive switching layer 402′ sandwiched between the bottom and top electrode layers 401 and 403 and acts as a resistive switching layer in the RRAM device 40. In some embodiments, the substrate W3 is made of a dielectric material, such as silicon oxide. In some embodiments, the bottom and top electrode layers 401 and 403 are made of a same material as each other, such as Aurum (Au). In some embodiments, the resistive switching layer 402′ may be made of a TMDC material, such as molybdenum disulfide (MoS₂). In some embodiments, the substrate W3 may have a thickness in a range from about 200 nm to about 400 nm, such as about 200, 250, 300, 350, or 400 nm, by way of example but not limiting the present disclosure. In some embodiments, the bottom electrode layer 401 may have a same thickness as the top electrode layer 403. In some embodiments, the bottom electrode layer 401 may have a different thickness than the top electrode layer 403. By way of example but not limiting the present disclosure, the bottom electrode layer 401 may have thickness in a range from about 50 nm to about 150 nm, such as about 50, 75, 100, 125, or 150 nm, and the top electrode layer 403 may have thickness in a range from about 50 nm to about 150 nm, such as about 50, 75, 100, 125, or 150 nm. In some embodiments, the top electrode layer 403 may have a line width D1 in a range from about nano scale to about micro scale, such as about 10, 50, 100, 150, 300, 400, 500, 600, 700, 800, or 1000 nm. In some embodiments, the resistive switching layer 402′ may have a thickness in a range from about 2 nm to about 10 nm, such as about 2, 3, 4, 5, 6, 7, 8, 9, or 10 nm, by way of example but not limiting the present disclosure.

FIGS. 6B-6D illustrate experimental results of a Raman spectrum of the resistive switching layer 402′ (sec FIG. 6A) made of the TMDC material, such as MoS₂, with different operation time durations, such as about 1 minute (see FIG. 6B), about 5 minutes (sec FIG. 6C), and about 7.5 minutes (scc FIG. 6D). Raman spectroscopy is a characterization technique for the resistive switching layer 402′ made of the TMDC material, such as MoS₂. FIG. 6B shows the Raman spectra collected from the as-grown resistive switching layer 402′ (see FIG. 6A) on the bottom electrode layer 401 with different micro-wave plasma power, such as about 15, 20, 25, 30, and 35 W, gencrated by the deposition system 14 as shown in FIG. 2F at operation time duration about 1 minute. FIG. 6C shows the Raman spectra collected from the as-grown resistive switching layer 402′ (see FIG. 6A) on the bottom electrode layer 401 with different micro-wave plasma power, such as about 15, 20, 25, 30, and 35 W. generated by the deposition system 14 as shown in FIG. 2F at operation time duration about 5 minutes. FIG. 6D shows the Raman spectra collected from the as-grown resistive switching layer 402′ (see FIG. 6A) on the bottom electrode layer 401 with different micro-wave plasma power, such as about 15, 20, 25, 30, and 35 W, generated by the deposition system 14 as shown in FIG. 2F at operation time duration about 7.5 minutes. Two characteristic Raman modes can be found in the spectra, the A_{1g} mode associated with the out-of-plane vibration of sulfur atoms and the E_{2g} mode related with the in-plane vibration of Mo and sulfur atoms. According to the samples for the resistive switching layer 402′ (see FIG. 6A) in FIGS. 6B-6D, the synthesized film growing at time durations in about 1, 5, and 7.5 minutes each has the A_{1g} mode and the E_{2g} mode, suggesting that the resistive switching layer 402′ for different growing time durations can have a good crystalline quality. In some embodiments, the A_{1g} mode can have a full width at half maximum (FWHM) in a range from about 7 cm⁻¹ to about 11 cm⁻¹, such as about 7 cm⁻¹, 8 cm⁻¹, 9 cm⁻¹, 10 cm⁻¹, or 11 cm⁻¹.

Reference is made to FIGS. 6E and 6F. FIG. 6E illustrates an optical image of the resistive switching layer 402′ grown on the bottom electrode layer 401, and the scale bar in the inset is about 6.25 nm. FIG. 6F illustrates an atomic force microscope (AFM) height profile for the resistive switching layer 402′ grown on the bottom electrode layer 401. The inset shows the AFM image from which the height profile is extracted. The thickness of the synthesized resistive switching layer 402′ is shown about 4 nm indicated by the AFM height profile shown in FIG. 6F. That is, the micro-wave plasma treatment performed on a transition metal layer can transform the transition metal layer to the TMDC layer having a thicker thickness (e.g. about 4 nm) than the transition metal layer e.g. about 1 nm). In some embodiments, the thickness of the TMDC layer can be greater than twice of the thickness of the transition metal layer.

FIGS. 6G and 6H respectively show molybdenum (Mo) and sulfur(S) X-ray photoelectron spectroscopy (XPS) data of a resultant sulfurized Mo layer of the RRAM device 40 in accordance with some embodiments of the present disclosure. The binding energy and atomic ratio of a resultant sulfurized Mo layer is checked using X-ray photoelectron spectroscopy (XPS). In FIG. 6G, the two peaks of Mo binding energy correspond to Mo⁴⁺ 3d_{5/2} and Mo⁴⁺ 3d_{3/2}, respectively. In FIG. 6H, the two peaks of S binding energy correspond to 2p_{3/2} and 2p_{1/2}, respectively. As confirmed by FIGS. 6G and 6H, the element composition ratio of S: Mo is in a range from about 1.8:1 to about 2.4:1, such as about 2.1:1. This indicates that the resultant sulfurized Mo layer in the RRAM device 40 can be a MoS₂ layer.

Reference is made to FIGS. 61 and 6J. FIG. 61 shows a current versus voltage plot for a DC sweep test on a RRAM device in accordance with some embodiments of the present disclosure. FIG. 6J shows a graph of DC sweep test results for the RRAM device with Vset and Vreset in accordance with an embodiment of the present invention. In FIG. 61, the horizontal axis represents a voltage applied to the RRAM device 40 (or a bias voltage applied to the bottom electrode in one example). The corresponding unit is volt (V). The vertical axis represents a current through the RRAM device 40. The corresponding unit is ampere (A). The current versus voltage plot is constructed according to experimental data from one sample of the RRAM device 40. The current versus voltage plot includes a set voltage range that is positive or in one polarity and a reset voltage range that is negative or in the opposite polarity. The operation “set” applies a set voltage in the set voltage range with a first polarity and the operation “reset” applies a reset voltage in the reset voltage range with a second polarity opposite from the polarity. Therefore, the operations of the RRAM device 40 are in a bipolar mode. In addition, a “forming” process (or operation) of the RRAM device 40 is described below. The forming process is designed to change the structure of the resistive switching layer 402′ of the RRAM device 40 such that a conductive path is generated therein, and filament features are generated in the resistive switching layer 402′ of the RRAM device 40. In the forming process, a forming voltage is applied to the two electrodes of the RRAM device 40. For example, the bottom electrode layer 401 is connected to a low voltage V_{low} and the top electrode layer 403 is connected to a high voltage V_{high}. The difference of V_{high}−V_{low} provides the forming voltage. In the “forming” operation, the “forming” voltage is high enough to generate conductive features in the resistive switching layer 402′. In some embodiments, the conductive features include a plurality of conductive filament to provide a conductive path such that the resistive switching layer 402′ is “on” or in low resistance state. In some embodiments, the forming voltage of the RRAM device 40 can be lower than about 0 V, such as about −1, −2, −2.35, −2.8, −3, −4, −4.2, or −4.5, such that the conductive filament can be broken in the operation of the RRAM device 40. By way of example but not limiting the present disclosure, as shown in FIG. 61, the forming voltage of the RRAM device 40 was about −2.35 V. In some embodiments, the Vset in the DC sweeps can be lower than about 1.55 V, and the Vreset in absolute value in the DC sweeps can be lower about 1.3 V, such that the RRAM device 40 can have a low operating voltage, which in turn improves the performance of the RRAM device 40. By way of example but not limiting the present disclosure, as shown in FIG. 6J, the Vset and Vreset in the DC sweeps were about 1.03 and −0.79 V, respectively.

Reference is made to FIGS. 6K-6M. FIGS. 6K and 6L respectively show graphs associated with DC sweep tests each including a high resistance state (HRS) and a low resistance state (LRS) in accordance with some embodiments of the present disclosure. FIG. 6M shows a resistance versus time plot for a DC sweep test with different currents and an off state on a RRAM device in accordance with some embodiments of the present disclosure. The DC sweep test as shown in FIGS. 61 and 6J include HRS and a LRS, and thus the resistive switching layer 402′ can able to function as data storage. The LRS and HRS represent “on” (or “1”) and “off” (or “0”), respectively, or vise versa. In some embodiments, the LRS and the HRS of the RRAM device 40 can have a resistance ratio (i.e., On/Off ratio) in a range from about 1×10⁵ to from about 1×10⁸, such as about 1×10⁵, 1×10⁶, 1×10⁷, or 1×10⁸. As shown in FIG. 6K, the LRS and the HRS have a resistance ratio about 2.5×10⁵, by way of example but not limiting the present disclosure. As shown in FIG. 6L, the LRS and the HRS have a resistance ratio about 1×10⁶, by way of example but not limiting the present disclosure. As part of the electrical performance testing process, the RRAM device 40 exhibited repeatable resistance switching behavior with a negative voltage sweep applied to the RRAM device 40, resetting the resistive switching layer 402′ to a HRS, and a positive voltage sweep setting it to a LRS again. In some embodiments, a repeating conversion between LRS and HRS show a retention characteristic of the RRAM device 40 can be greater than about 1000 seconds, by way of example but not limiting the present disclosure. In FIG. 6M, the resistance versus time plot for a DC sweep test with different currents, such as 10⁻³, 10⁻⁴, 10⁻⁵, 10⁻⁶, 10⁻⁷, and an off state on the RRAM device 40. The resistance versus time plot shows that the RRAM device 40 can be functioned at different currents, which in turn shows a multistate characteristic.

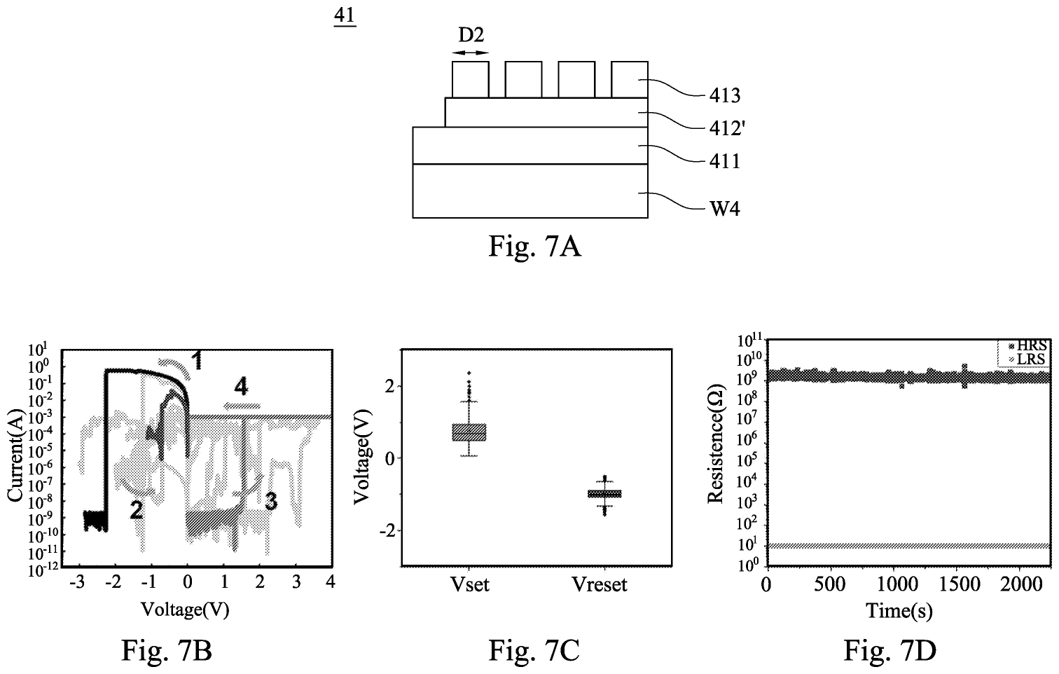

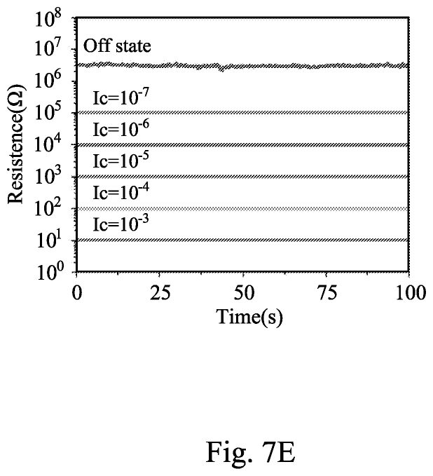

Reference is made to FIGS. 7A-7E. FIG. 7A is a schematic diagram of a semiconductor structure in accordance with some embodiments of the present disclosure. FIGS. 7B-7E illustrate experimental results of the semiconductor structure of FIG. 7A. As shown in FIG. 7A, a RRAM device 41 is provided. The RRAM device 41 is formed by a fabrication process as shown in FIGS. 2A-2H. In some embodiments, the RRAM device 41 may include a substrate W4, a bottom electrode layer 411, a top electrode layer 413, and a resistive switching layer 412′ sandwiched between the bottom and top electrode layers 411 and 413 and acts as a resistive switching layer in the RRAM device 41. In some embodiments, the substrate W4 is made of a dielectric material, such as silicon oxide. In some embodiments, the bottom electrode layer 411 is made of a different material than the top electrode layer 413. By way of example but not limiting the present disclosure, the bottom electrode layer 411 is made of Aurum (Au), and the top electrode layer 413 is made of argentum (Ag). In some embodiments, the resistive switching layer 412′ may be made of a TMDC material, such as MoS₂. In some embodiments, the substrate W4 may have a thickness in a range from about 200 nm to about 410 nm, such as about 200, 250, 300, 350, or 400 nm, by way of example but not limiting the present disclosure. In some embodiments, the bottom electrode layer 411 may have a same thickness as the top electrode layer 413. In some embodiments, the bottom electrode layer 411 may have a different thickness than the top electrode layer 413. By way of example but not limiting the present disclosure, the bottom electrode layer 411 may have thickness in a range from about 50 nm to about 150 nm, such as about 50, 75, 100, 125, or 150 nm, and the top electrode layer 413 may have thickness in a range from about 50 nm to about 150 nm, such as about 50, 75, 100, 125, or 150 nm. In some embodiments, the top electrode layer 413 may have a line width D2 in a range from about nano scale to about micro scale, such as about 10, 50, 100, 150, 300, 400, 500, 600, 700, 800, or 1000 nm. In some embodiments, the resistive switching layer 412′ may have a thickness in a range from about 2 nm to about 10 nm, such as about 2, 3, 4, 5, 6, 7, 8, 9, or 10 nm, by way of example but not limiting the present disclosure.

Reference is made to FIGS. 7B and 7C. FIG. 7B shows a current versus voltage plot for a DC sweep test on a RRAM device in accordance with some embodiments of the present disclosure. FIG. 7C shows a graph of DC sweep test results for the RRAM device with Vset and Vreset in accordance with an embodiment of the present invention. In FIG. 7B, the horizontal axis represents a voltage applied to the RRAM device 41 (or a bias voltage applied to the bottom electrode in one example). The corresponding unit is volt (V). The vertical axis represents a current through the RRAM device 41. The corresponding unit is ampere (A). The current versus voltage plot is constructed according to experimental data from one sample of the RRAM device 41. The current versus voltage plot includes a set voltage range that is positive or in one polarity and a reset voltage range that is negative or in the opposite polarity. The operation “set” applies a set voltage in the set voltage range with a first polarity and the operation “reset” applies a reset voltage in the reset voltage range with a second polarity opposite from the polarity. Therefore, the operations of the RRAM device 41 are in a bipolar mode. In addition, a “forming” process (or operation) of the RRAM device 41 is described below. The forming process is designed to change the structure of the resistive switching layer 412′ of the RRAM device 41 such that a conductive path is generated therein, and filament features are generated in the resistive switching layer 412′ of the RRAM device 41. In the forming process, a forming voltage is applied to the two electrodes of the RRAM device 41. For example, the bottom electrode layer 411 is connected to a low voltage V_{low} and the top electrode layer 413 is connected to a high voltage V_{high}. The difference of V_{high}−V_{low} provides the forming voltage. In the “forming” operation, the “forming” voltage is high enough to generate conductive features in the resistive switching layer 412′. In some embodiments, the conductive features include a plurality of conductive filament to provide a conductive path such that the resistive switching layer 412′ is “on” or in low resistance state. In some embodiments, the forming voltage of the RRAM device 41 can be lower than about 0 V, such as about −1, −2, −2.35, −2.8, −3, −4, −4.2, or −4.5, such that the conductive filament can be broken in the operation of the RRAM device 41. By way of example but not limiting the present disclosure, as shown in FIGS. 7B, the forming voltage of the RRAM device 41 was about −2.8 V. In some embodiments, the Vset in the DC sweeps can be lower than about 1.55 V, and the Vreset in absolute value in the DC sweeps can be lower about 1.3 V, such that the RRAM device 41 can have a low operating voltage, which in turn improves the performance of the RRAM device 41. By way of example but not limiting the present disclosure, as shown in FIGS. 7C, the Vset and Vreset in the DC sweeps were about 0.8 and −0.85 V, respectively.

Reference is made to FIGS. 7D and 7E. FIG. 7D shows a graph associated with a DC sweep test including a HRS and a LRS in accordance with some embodiments of the present disclosure. FIG. 7E shows a resistance versus time plot for a DC sweep test with different currents and an off state on a RRAM device in accordance with some embodiments of the present disclosure. The DC sweep test as shown in FIG. 7D includes a HRS and a LRS, and thus the resistive switching layer 412′ can be able to function as data storage. In some embodiments, the LRS and the HRS of the RRAM device 41 can have a resistance ratio (i.e., On/Off ratio) in a range from about 1×10⁵ to from about 1×10⁸, such as about 1×10⁵, 1×10⁶, 1×10⁷, or 1×10⁸. As shown in FIG. 7D, the LRS and the HRS have a resistance ratio about 1×10⁸, by way of example but not limiting the present disclosure. As part of the electrical performance testing process, the RRAM device 41 exhibited repeatable resistance switching behavior with a negative voltage sweep applied to the RRAM device 41, resetting the resistive switching layer 412′ to a HRS, and a positive voltage sweep setting it to a LRS again. In some embodiments, a repeating conversion between LRS and HRS show a retention characteristic of the RRAM device 41 can be greater than about 3000 seconds, by way of example but not limiting the present disclosure. In FIG. 7E, the resistance versus time plot for a DC sweep test with different currents, such as 10⁻³, 10⁻⁴, 10⁻⁵, 10⁻⁶, 10⁻⁷, and an off state on the RRAM device 41. The resistance versus time plot shows that the RRAM device 41 can be functioned at different currents, which in turn shows a multistate characteristic.

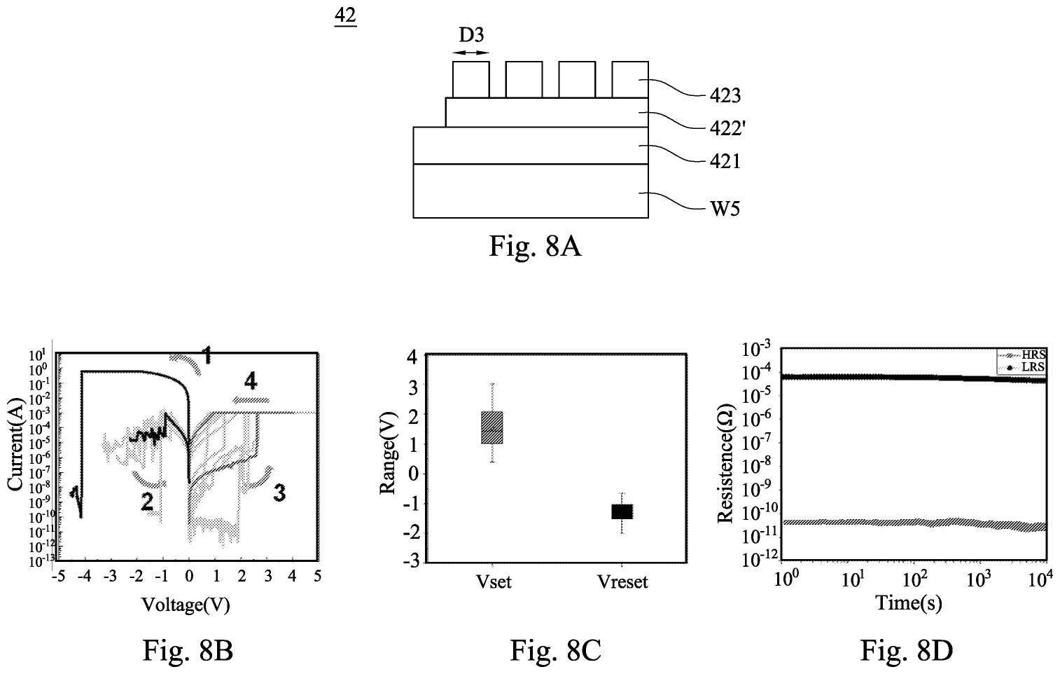

Reference is made to FIGS. 8A-8D. FIG. 8A is a schematic diagram of a semiconductor structure in accordance with some embodiments of the present disclosure. FIGS. 8B-8D illustrate experimental results of the semiconductor structure of FIG. 8A. As shown in FIG. 8A, a RRAM device 42 is provided. The RRAM device 42 is formed by a fabrication process as shown in FIGS. 2A-2H. In some embodiments, the RRAM device 42 may include a substrate W5, a bottom electrode layer 421, a top electrode layer 423, and a resistive switching layer 422′ sandwiched between the bottom and top electrode layers 421 and 423 and acts as a resistive switching layer in the RRAM device 42. In some embodiments, the substrate W5 is made of a dielectric material, such as silicon oxide. In some embodiments, the bottom electrode layer 411 is made of a different material than the top electrode layer 413. By way of example but not limiting the present disclosure, the bottom electrode layer 411 is made of Aurum (Au), and the top electrode layer 413 is made of copper (Cu). In some embodiments, the resistive switching layer 422′ may be made of a TMDC material, such as MoS₂. In some embodiments, the substrate W5 may have a thickness in a range from about 200 nm to about 420 nm, such as about 200, 250, 300, 350, or 400 nm, by way of example but not limiting the present disclosure. In some embodiments, the bottom electrode layer 421 may have a same thickness as the top electrode layer 423. In some embodiments, the bottom electrode layer 421 may have a different thickness than the top electrode layer 423. By way of example but not limiting the present disclosure, the bottom electrode layer 421 may have thickness in a range from about 50 nm to about 150 nm, such as about 50, 75, 100, 125, or 150 nm, and the top electrode layer 423 may have thickness in a range from about 50 nm to about 150 nm, such as about 50, 75, 100, 125, or 150 nm. In some embodiments, the top electrode layer 423 may have a line width D3 in a range from nano scale to about micro scale, such as about 10, 50, 100, 150, 300, 400, 500, 600, 700, 800, or 1000 nm. In some embodiments, the resistive switching layer 412′ may have a thickness in a range from about 2 nm to about 10 nm, such as about 2, 3, 4, 5, 6, 7, 8, 9, or 10 nm, by way of example but not limiting the present disclosure.

Reference is made to FIGS. 8B and 8C. FIG. 8B shows a current versus voltage plot for a DC sweep test on a RRAM device in accordance with some embodiments of the present disclosure. FIG. 8C shows a graph of DC sweep test results for the RRAM device with Vset and Vreset in accordance with an embodiment of the present invention. In FIG. 8B, the horizontal axis represents a voltage applied to the RRAM device 42 (or a bias voltage applied to the bottom electrode in one example). The corresponding unit is volt (V). The vertical axis represents a current through the RRAM device 42. The corresponding unit is ampere (A). The current versus voltage plot is constructed according to experimental data from one sample of the RRAM device 42. The current versus voltage plot includes a set voltage range that is positive or in one polarity and a reset voltage range that is negative or in the opposite polarity. The operation “set” applies a set voltage in the set voltage range with a first polarity and the operation “reset” applies a reset voltage in the reset voltage range with a second polarity opposite from the polarity. Therefore, the operations of the RRAM device 42 are in a bipolar mode. In addition, a “forming” process (or operation) of the RRAM device 42 is described below. The forming process is designed to change the structure of the resistive switching layer 422′ of the RRAM device 42 such that a conductive path is generated therein, and filament features are generated in the resistive switching layer 422′ of the RRAM device 42. In the forming process, a forming voltage is applied to the two electrodes of the RRAM device 42. For example, the bottom electrode layer 421 is connected to a low voltage V_{low} and the top electrode layer 423 is connected to a high voltage V_{high}. The difference of V_{high}−V_{low} provides the forming voltage. In the “forming” operation, the “forming” voltage is high enough to generate conductive features in the resistive switching layer 422′. In some embodiments, the conductive features include a plurality of conductive filament to provide a conductive path such that the resistive switching layer 422′ is “on” or in low resistance state. In some embodiments, the forming voltage of the RRAM device 40 can be lower than about 0 V, such as about −1, −2, −2.35, −2.8, −3, −4, −4.2, or −4.5, such that the conductive filament can be broken in the operation of the RRAM device 42. By way of example but not limiting the present disclosure, as shown in FIG. 8B, the forming voltage of the RRAM device 42 was about −4.2 V. In some embodiments, the Vset in the DC sweeps can be lower than about 1.55 V, and the Vreset in absolute value in the DC sweeps can be lower about 1.3 V, such that the RRAM device 42 can have a low operating voltage, which in turn improves the performance of the RRAM device 42. By way of example but not limiting the present disclosure, as shown in FIG. 8C, the Vset and Vreset in the DC sweeps were about 1.52 and −1.29 V, respectively.

Reference is made to FIG. 8D. FIG. 8D shows a graph associated with a DC sweep test including a HRS and a LRS in accordance with some embodiments of the present disclosure. The DC sweep test as shown in FIG. 8D includes a HRS and a LRS, and thus the resistive switching layer 422′ can be able to function as data storage. In some embodiments, the LRS and the HRS of the RRAM device 42 can have a resistance ratio (i.e., On/Off ratio) in a range from about 1×10⁵ to from about 1×10⁸, such as about 1×10⁵, 1×10⁶, 1×10⁷, or 1×10⁸. As shown in FIG. 7D, the LRS and the HRS have a resistance ratio about 1×10⁸, by way of example but not limiting the present disclosure. As part of the electrical performance testing process, the RRAM device 42 exhibited repeatable resistance switching behavior with a negative voltage sweep applied to the RRAM device 42, resetting the resistive switching layer 422′ to a HRS, and a positive voltage sweep setting it to a LRS again. In some embodiments, a repeating conversion between LRS and HRS show a retention characteristic of the RRAM device 42 can be greater than about 10000 seconds, by way of example but not limiting the present disclosure.

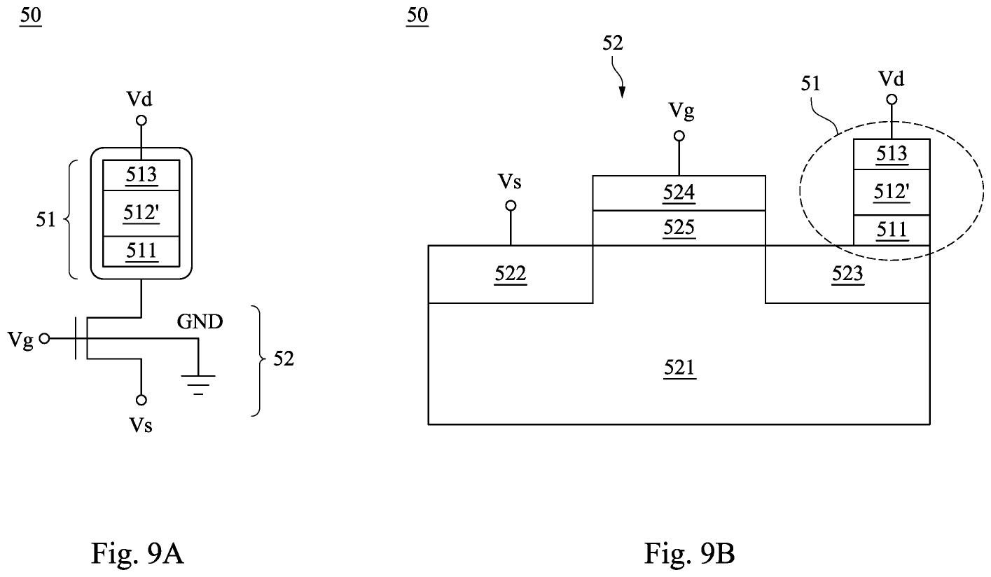

Reference is made to FIGS. 9A and 9B. FIG. 9A illustrates a circuit diagram of an RRAM in accordance with some embodiments of the present disclosure. FIG. 9B is a schematic diagram of a semiconductor structure corresponding to FIG. 9A. In FIGS. 9A and 9B, a 1-transistor-1-resistor (1T1R) structure 50 with a memory structure 51 is provided. In some embodiments, the memory structure 51 includes a bottom electrode layer 511, a top electrode layer 513, and a resistive switching layer 512′ between the bottom electrode layer 511 and the top electrode layer 513. In some embodiments, the bottom electrode layer 511 and/or the top electrode layer 513 may be made of a conductive material, such as iron (Fe), cobalt (Co), nickel (Ni), copper (Cu), platinum (Pt), palladium (Pd), aluminum (Al), tungsten (W), ruthenium (Ru), Au, Ti, Ta, TiN, TaN, proper alloys thereof, the like, suitable materials, or combinations thereof. In some embodiments, the bottom electrode layer 511 may be made of a same material as the top electrode layer 513. In some embodiments, the bottom electrode layer 511 may be made of a different material than the top electrode layer 513. In some embodiments, the resistive switching layer 512′ may include transition metal, such as Mo, W, Pd, Pt, the like, or combinations thereof. In some embodiments, the resistive switching layer 512′ can be interchangeably referred to as a transition metal layer. An end of a conductor 53 is electrically connected to the bottom electrode layer 511 of the memory structure 51, and another end of the conductor 53 is electrically connected to a drain region 523 of a transistor 52. The transistor 52 shown in FIG. 9B includes a substrate 521, a source 522, a drain 523, a gate 524, and an oxide layer 525 between the substrate 521 and the gate 524. Voltage difference between the bottom electrode layer 511 (or effectively drain 523) and the top electrode layer 513 can triggers the forming, the SET, and the RESET process of the conductive filaments in the resistive switching layer 512′ of the memory structure 51. In some embodiments, the oxide layer 525 can be interchangeably referred to as an insulator.

Reference is made to FIGS. 10A-10Q. FIGS. 10A-10Q illustrate a method in various stages of forming a semiconductor structure in accordance with some embodiments of the present disclosure. Reference is made to FIG. 10A. An initial structure is received. The initial structure includes a substrate 610. The substrate 610 includes an N-well region 600N and a P-well region 600P, in which the N-well region 600N may be doped with N-type impurities, and the P-well region 600P may be doped with P-type impurities. The substrate 610 may be a semiconductor material and may include known structures including a graded layer or a buried oxide, for example. Other materials, such as germanium, quartz, sapphire, and glass could alternatively be used for the substrate 610. Alternatively, the silicon substrate 610 may be an active layer of a semiconductor-on-insulator (SOI) substrate or a multi-layered structure such as a silicon-germanium layer formed on a bulk silicon layer. Isolation structures 605 are disposed in the substrate 610. In some embodiments, the isolation structures 605 may include oxide, such as silicon dioxide. The isolation structures 605, which act as a shallow trench isolation (STI) around the P-well region 600P from the N-well region 600N, may be formed by chemical vapor deposition (CVD) techniques using tetra-ethyl-ortho-silicate (TEOS) and oxygen as a precursor.

A gate structure 600A is disposed over the P-well region 600P of the substrate 610, and a gate structure 600B is disposed over the N-well region 600N of the substrate 610. In some embodiments, each of the gate structure 600A and the gate structure 600B includes a gate dielectric 602 and a gate electrode 604. In some embodiments, the gate dielectric 602 may be, for example, silicon oxide, silicon nitride, a combination thereof, or the like, and may be deposited or thermally grown according to acceptable techniques. In some embodiments, the gate electrode 604 may include polycrystalline-silicon (poly-Si) or poly-crystalline silicon-germanium (poly-SiGe). In some embodiments, the gate structure 600A and the gate structure 600B may be metal gate structures, which include a high-k dielectric layer, a work function metal layer over the high-k dielectric layer, and a gate metal over the work function metal layer. Capping layers 625 are disposed over the gate structures 600A and 600B. In some embodiments, the capping layers 625 may be oxide.

Source/drain structures 620N are disposed in the P-well region 620P of the substrate 610 and on opposite sides of the gate structure 600A, and source/drain structures 620P are disposed in the N-well region 620N of the substrate 610 and on opposite sides of the gate structure 600B. In some embodiments, the source/drain structures 620N may be doped with N-type impurities, and the source/drain structures 620P may be doped with p-type impurities. In some embodiments, the source/drain structures 620N, 620P may be may be formed by performing an epitaxial growth process that provides an epitaxy material over the substrate 610, and thus the source/drain structures 620N, 620P can be interchangeably referred to as epitaxy structures 620N, 620P in this context. In various embodiments, the source/drain structures 620N, 620P may include Ge, Si, GaAs, AlGaAs, SiGe, GaAsP, SiP, or other suitable materials.

A contact etch stop layer (CESL) 630 is disposed over the isolation structures 605 and over the capping layers 625. An interlayer dielectric (ILD) layer 640 is disposed over the CESL 630 and surrounds the gate structures 600A and 600B. In some embodiments, the CESL 630 includes silicon nitride, silicon oxynitride or other suitable materials. The CESL 630 can be formed using, for example, plasma enhanced CVD, low pressure CVD, ALD or other suitable techniques. In some embodiments, the ILD layer 640 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide. The ILD layer 640 may be formed using, for example, CVD, ALD, spin-on-glass (SOG) or other suitable techniques.

Source/drain contacts 650 are disposed in the ILD layer 640 and contact the source/drain structures 620A and 620P. In some embodiments, each source/drain contact 650 includes a liner 652 and a plug 654. The liner 652 is between the plug 654 and the underlying source/drain structures 600A or 600B. In some embodiments, the liner 652 assists with the deposition of the plug 654 and helps to reduce diffusion of a material of the plug 654 through the gate spacers 612. In some embodiments, the liner 652 includes titanium (Ti), titanium nitride (TiN), tantalum (Ta), tantalum nitride (TaN), or another suitable material. The plug 654 includes a conductive material, such tungsten (W), copper (Cu), aluminum (Al), ruthenium (Ru), cobalt (Co), molybdenum (Mo), nickel (Ni), or other suitable conductive materials.

An etch stop layer (ESL) 700 is disposed over the ILD layer 640 and the source/drain contacts 650. An inter-metal dielectric (IMD) layer 705 is disposed over the ESL 700. The material and the formation method of the ESL 700 are similar to those of the CESL 630. Moreover, the material and the formation method of the IMD layer 705 are similar to those of the ILD layer 640. In some embodiments, the ESL 700 can be interchangeably referred to as a trench etch stop layer.

Reference is made to FIG. 10B. The ESL 700 and the IMD layer 705 are patterned to form openings O1. Subsequently, a liner 710 and a metal seed layer 715 are formed in the openings O1. In some embodiments, the liner 710 includes titanium (Ti), titanium nitride (TiN), tantalum (Ta), tantalum nitride (TaN), or another suitable material. The metal seed layer 715 may be copper (Cu), cobalt (Co), nickel (Ni), ferrum (Fe), or suitable conductive materials. In some embodiments, the liner 710 can be interchangeably referred to as a barrier or a bottom electrode material barrier (e.g., Cu barrier).

Reference is made to FIG. 10C. A filling material 730 is deposited over the metal seed layer 715 and fills the openings O1. In some embodiments, the filling material 730 may include noble metal. In some embodiments, the filling metal 730 is made of a conductive material. In some embodiments, the conductive material may include iron (Fe), cobalt (Co), nickel (Ni), copper (Cu), platinum (Pt), palladium (Pd), aluminum (Al), tungsten (W), ruthenium (Ru), Ti, Ta, TiN, TaN, proper alloys thereof, suitable materials, or combinations thereof. In some embodiments, the conductive material may be deposited by CVD, physical vapor deposition (PVD), sputter deposition, ALD. electroplating, or other techniques suitable for depositing conductive materials. Subsequently, an annealing process can be performed on the filling material 730.

Reference is made to FIG. 10D. A chemical mechanical polishing (CMP) process is performed to remove excessive materials of the filling material 730, the liner 710, and the metal seed layer 715 until the IMD layer 705 is exposed. In some embodiments, the remaining the filling material 730, the liner 710, and the metal seed layer 715 can be referred to as a bottom electrode of a RRAM device. In some embodiments, the remaining filling metal 730, the metal seed layer 715, and the liner 710 can be referred to as metal-1 (M1) layer in a back end of line (BEOL) process.

Reference is made to FIG. 10E. An ESL 800 and an ILD layer 802 are formed sequentially over the IMD layer 705. The ESL 800 is similar to the ESL 700, and the ILD layer 802 is similar to the IMD layer 705, and thus relevant details will not be repeated for brevity. In some embodiments, the ESL 800 can be interchangeably referred to as a via etch stop layer

Reference is made to FIG. 10F. The ESL 800 and the ILD layer 802 are patterned to form openings O2. In some embodiments, the openings O2 are aligned with and expose the bottom electrode materials 730. In some embodiments, openings O2 may be formed by, for example, forming a patterned photoresist layer over the ILD layer 802, followed by an etching process to remove portions of the ESL 800 and the ILD layer 802, and then removing the photoresist layer.

Reference is made to FIG. 10G. A bottom electrode material 830 is deposited over the ESL 800 and the ILD layer 802 and fills the openings O2. In some embodiments, the bottom electrode material 830 may include noble metal. In some embodiments, the bottom electrode material 830 may be made of a conductive material, such as iron (Fe), cobalt (Co), nickel (Ni), copper (Cu), platinum (Pt), palladium (Pd), aluminum (Al), tungsten (W), ruthenium (Ru), Au, Ti, Ta, TiN, TaN, proper alloys thereof, the like, suitable materials, or combinations thereof. In some embodiments, the bottom electrode material 830 may be formed by a deposition process, such as a physical vapor deposition (PVD) process (e.g., e-gun evaporation deposition or thermal evaporation deposition), an atomic layer deposition (ALD), a chemical vapor deposition (CVD), the like, or combinations thereof. In some embodiments, the thermal evaporation deposition may be performed by the deposition system 10 as shown in FIG. 2B.

Reference is made to FIG. 10H. A chemical mechanical polishing (CMP) process is performed to remove excessive materials of the bottom electrode material 830 until the IMD layer 802 is exposed. In some embodiments, the remaining bottom electrode material 830 can be referred to as a bottom electrode of a RRAM device. In some embodiments, the bottom electrode material 830 may have a thickness in a range from about 10 nm to about 100 nm, by way of example but not limiting the present disclosure.

Reference is made to FIG. 10I. An ESL 900 and an ILD layer 902 are formed sequentially over the bottom electrode material 830 and the ILD layer 902. The ESL 900 is similar to the ESL 700, and the ILD layer 902 is similar to the ILD layer 705, and thus relevant details will not be repeated for brevity. In some embodiments, the ESL 900 can be interchangeably referred to as a via etch stop layer.

Reference is made to FIG. 10J. The ESL 900 and the ILD layer 902 are patterned to form openings O3. In some embodiments, the openings O3 are aligned with and expose the bottom electrode material 830. In some embodiments, openings O3 may be formed by, for example, forming a patterned photoresist layer over the ILD layer 902, followed by an etching process to remove portions of the ESL 900 and the IMD layer 902, and then removing the photoresist layer.

Reference is made to FIG. 10K. A transition metal 930 is deposited over the ILD layer 902 and fills the openings O3. In some embodiments, the transition metal layer 102 may include transition metal, such as Mo, W, Pd, Pt, the like, or combinations thereof. In some embodiments, the transition metal layer 102 may be formed by a deposition process P3, such as a physical vapor deposition (PVD) process (e.g., e-gun evaporation deposition or thermal evaporation deposition), an atomic layer deposition (ALD), a chemical vapor deposition (CVD), the like, or combinations thereof. In some embodiments, the e-gun evaporation deposition may be performed by a deposition system 12 as shown in FIG. 2D.

Reference is made to FIG. 10L. A chemical mechanical polishing (CMP) process is performed to remove excessive materials of the transition metal 930 until the ILD layer 902 is exposed.

Reference is made to FIG. 10M. The transition metal 930 is chalcogenized by the PECVD system 14 as shown in FIG. 2F, such that a TMDC 930′ is formed on the bottom electrode material 830 as a resistive switching layer of the RRAM device. This is described in greater detail, the substrate 610 can be placed over the substrate holder 142 of the PECVD system 14. In some embodiments, the substrate 610 can be supported by the protruding edges 142P of the substrate holder 142 of the PECVD system 14 without contacting the base portion 142B of the substrate holder 142. The precursor gas flows across the substrate 610 and hence reacts with the transition metal 930 (see FIG. 10L) to form TMDC 930′ on the bottom electrode material 830. This is described in greater detail, the transition metal 930 is chalcogenized by a micro-wave plasma treatment performed by the PECVD system 14. In some embodiments, the gas flow GF shown in FIG. 2F containing chalcogen is directed to the plasma generator 141 of the PECVD system 14, and then the plasma generator 141 is used to ionize the gas flow GF to create the plasma around the transition metal 930 in the processing chamber 140 of the PECVD system 14. In some embodiments, the gas sources 144 and 145 of the PECVD system 14 are configured to provide a gas flow containing a mixture of Ar and H₂ to the processing chamber 140 of the PECVD system 14. After the gas flow GF passes the portion 140a of the processing chamber 140, the heated chalcogen precursor 160 of the PECVD system 14 may add chalcogen gas to the gas flow GF. The plasma generator 141 receives microwaves from the power supply 122 of the PECVD system 14, and then the microwaves ionize the gas flow GF with the chalcogen gas and thus generate plasma when microwave energy is high enough. The transition metal 930 on the substrate 610 reacts with the chalcogen in the plasma, and turns to the TMDC 930′. In some embodiments, depending on the chalcogen contained in the gas flow GF as shown in FIG. 2F, the chalcogenizing process (e.g., turning the transition metal 930 into the TMDC 930′) may be referred to as sulfurizing process, selenizing process, or the like. TMDCs are a class of materials with the chemical formula MX₂, wherein M is a transition metal element such as titanium, vanadium, cobalt, nickel, zirconium, molybdenum, technetium, rhodium, palladium, hafnium, tantalum, tungsten, rhenium, iridium, platinum, and X is a chalcogen such as sulfur, selenium, or tellurium. Examples of TMDC may include MoS₂, WS₂, WSe₂, MoSe₂, MoTe₂, WTe₂, the like, or combinations thereof. During the chalcogenizing process, some species may be in-situ doped into the TMDC 930′ by fluidly connecting the doping source to the gas inlet 1401 of the PECVD system 14. In some embodiments, the transition metal 930 can be sulfide by micro-wave plasma generated by the PECVD system 14 to form TMDC 930′, such as MoS₂.

Once formed, the TMDC 930′ is in a layered structure with one or a plurality of two-dimensional layers of the general form X-M-X, with the chalcogen atoms in two planes separated by a plane of metal atoms. The TMDC 930′ may be a mono-layer or may include a few mono-layers, depending on thickness of the transition metal 930 (see FIG. 10L). By way of example but not limiting the present disclosure, if the TMDC 930′ is in a one-molecule thick, the TMDC 930′ may include transition metal atoms forming a layer in a middle region thereof and chalcogen atoms forming a first layer over the layer of transition metal atoms and a second layer underlying the layer of transition metal atoms. The transition metal atoms may be W atoms or Mo atoms, while the chalcogen atoms may be S atoms, Se atoms, or Te atoms. In the example of the TMDC 930′ is in a one-molecule thick, each of the transition metal atoms is bonded (e.g., by covalent bonds) to six chalcogen atoms, and each of the chalcogen atoms is bonded (e.g. by covalent bonds) to three transition metal atoms. Throughout the description, the illustrated cross-bonded layers including one layer of transition metal atoms and two layers of chalcogen atoms in combination are referred to as a mono-layer of the TMDC 930′. In some further embodiments, by depositing the transition metal 930 (referring to FIG. 10L) with suitable thicknesses and etching the transition metal 930 (referring to FIG. 10L) with desired patterns, the resultant TMDC 930′ may be formed with suitable thicknesses and desired patterns.

In some embodiments, since the microwave plasma is reaction trigger, the plasma can be formed intensively with a high energy in the desired region, such that a transition metal 930 (see FIG. 10L) can be turned into a TMDC 930′ without heating the substrate 610 (e.g., using a heating device in contact with the substrate 610 to directly heat the substrate 610). Through the configuration, the TMDC 930′ is synthesized at a low temperature. For example, a temperature of the processing chamber 140 can be controlled below about 400° C., which may reduce the thermal budget. Thermal budget may be referred to as total amount of thermal energy transferred to the wafer during the given elevated temperature operation, and low thermal budget is desired in IC manufacturing to prevent dopant redistribution. Also, in some embodiments of the present disclosure, the TMDC 930′ is formed without heating the substrate 610 (e.g., using a heating device in contact with the substrate 610 to directly heat the substrate 610), thereby the process for heating and cooling the substrate 610 is not required, which in turn will lead to short process time.

In some embodiments, during the plasma treatment on the transition metal 930, the operating power of the power supply 122 of the PECVD system 14 may be in a range from about 10 W to about 40 W, such as about 10, 15, 20, 25, 30, 35, or 40 W. If the power is lower than about 10 W, it is hard to form plasma. If the power is higher than about 40 W, the substrate or a peripheral region of the substrate may be damaged by plasma. In some embodiments, the micro-wave plasma treatment is performed at a frequency in a range from about 2000 to 3000 MHz, such as about 2000, 2100, 2200, 2300, 2400, 2450, 2500, 2600, 2700, 2800, 2900, or 3000 MHz. In some embodiments, during the plasma treatment on the transition metal 930, a flow rate of the gas flow GF provided by the gas sources 144 and 145 of the PECVD system 14 is in a range from about 1 standard cubic centimeter per minute (sccm) to about 10 sccm, such as about 1, 2, 3, 4, 5, 6, 7, 8, 9, or 10 sccm. The gas flow GF may include a reactive gas mixture of H₂, Ar, and H₂S. If the flow rate of the gas flow GF is lower than about 1 sccm, it is hard to form plasma. If the flow rate of the gas flow GF is greater than about 10 sccm, the chalcogen gas (e.g., H₂S) may move too fast to react with metal film, and the pressure may be too high to form plasma. In some embodiments, during the plasma treatment on the transition metal 930, the process pressure of the processing chamber 140, for example, monitored by the pressure gauge 152 of the PECVD system 14, is in a range from several mTorrs to hundreds of mTorrs. For example, the process pressure of the processing chamber 140 may be in a range from about 1×10⁻¹ to about 1×10⁻² torr. If the pressure is higher than about 1×10⁻¹ torr, the ionization efficiency is low, and it may not be easy to form plasma. If the pressure is lower than about 1×10⁻², the voltage to break down the gas is high, and therefore it may not be easy to form plasma. In some embodiments, a time duration for performing the plasma treatment on the transition metal 930 is in a range from about 1 minute to about 30 minutes, such as about 1, 2, 3, 4, 5, 6, 7, 8, 9, 10, 11, 12, 13, 14, 15, 16, 17, 18, 19, 20, 21, 22, 23, 24, 25, 26, 27, 28, 29, or 30 minutes. If the time duration is less about 1 minute, the chalcogenizing reaction may be incomplete, which may result in non-uniform chalcogenized metal layers. If the time duration is greater than about 15 minutes, long-time exposure to plasma may result in rough surface damage, and it may unnecessarily increase process time. In some embodiments, a time duration for performing the plasma treatment on the transition metal layer 930 can be less than about 10 minutes. In some embodiments, the TMDC 930′ may have a thickness in a range from about 2 nm to about 10 nm, such as about 2, 3, 4, 5, 6, 7, 8, 9, or 10 nm, by way of example but not limiting the present disclosure. In some embodiments, the TMDC 930′ has a Raman spectrum including a A_{1g} mode and a E_{2g} mode, the A_{1g} mode having a full width at half maximum (FWHM) in a range from about 7 cm⁻¹ to about 11 cm⁻¹.

Reference is made to FIG. 10N. An ESL 1000 and an ILD layer 1002 are formed sequentially over the TMDC 930′ and the ILD layer 902. The ESL 1000 is similar to the ESL 700, and the ILD layer 1002 is similar to the IMD layer 705, and thus relevant details will not be repeated for brevity.

Reference is made to FIG. 100. The ESL 1000 and the ILD layer 1002 are patterned to form openings O4. In some embodiments, the openings O4 are aligned with and expose the TMDC 930′. In some embodiments, openings O4 may be formed by, for example, forming a patterned photoresist layer over the ILD layer 1002, followed by an etching process to remove portions of the ESL 1000 and the ILD layer 1002, and then removing the photoresist layer.

Reference is made to FIG. 10P. A top electrode material 1030 is deposited over the ILD layer 1002 and fills the openings O4. In some embodiments, the top electrode material 1030 may include noble metal. In some embodiments, the top electrode material 1030 may be made of a conductive material, such as iron (Fe), cobalt (Co), nickel (Ni), copper (Cu), platinum (Pt), palladium (Pd), aluminum (Al), tungsten (W), ruthenium (Ru), Au, Ti, Ta, TiN, TaN, proper alloys thereof, the like, suitable materials, or combinations thereof. In some embodiments, the top electrode material 1030 may be formed by a deposition process, such as a physical vapor deposition (PVD) process (e.g., e-gun evaporation deposition or thermal evaporation deposition), an atomic layer deposition (ALD), a chemical vapor deposition (CVD), the like, or combinations thereof. In some embodiments, the thermal evaporation deposition may be performed by the deposition system 10 as shown in FIG. 2B. In some embodiments, the top electrode material 1030 may be made of a different material than the bottom electrode material 830. In some embodiments, the top electrode material 1030 may be made of a same material as the bottom electrode material 830.

Reference is made to FIG. 10Q. A chemical mechanical polishing (CMP) process is performed to remove excessive materials of the top electrode material 1030 until the ILD layer 1002 is exposed. In some embodiments, the remaining top electrode material 1030 can be referred to as a top electrode of the RRAM device. In some embodiments, the top electrode material 1030 may have a thickness in a range from about 10 nm to about 100 nm, by way of example but not limiting the present disclosure. In some embodiments, the forming voltage of the RRAM device shown in FIG. 10Q can be lower than about 0 V, such as about −1, −2, −2.35, −2.8, −3, −4, −4.2, or −4.5, such that the conductive filament can be broken in the operation of the RRAM device 40. In some embodiments, the Vset in the DC sweeps of the RRAM device shown in FIG. 10Q can be lower than about 1.55 V, and the Vreset of the RRAM device shown in FIG. 10Q in absolute value in the DC sweeps can be lower about 1.3 V, such that the RRAM device can have a low operating voltage, which in turn improves the performance of the RRAM device.

Therefore, based on the above discussions, it can be seen that the present disclosure offers advantages. It is understood, however, that other embodiments may offer additional advantages, and not all advantages are necessarily disclosed herein, and that no particular advantage is required for all embodiments. The present disclosure in various embodiments provides a plasma-enhanced chemical vapor deposition (PECVD) process performed at a low-temperature (e.g. lower than about 400° C.) and a low-process time duration (e.g. lower than about 30 minutes) with a chalcogen precursor to form a resistive switching layer including a transition metal dichalcogenide (TMDC) material. Because the formation of the resistive switching layer can be performed at a temperature lower about 400° C. and a process time duration lower about 30 minutes, a lower thermal budget to synthesize the resistive switching layer in the RRAM device is reached, such that the performance of an IC structure can be improved. For example, the resistive switching layer can be formed on the bottom electrode of RRAM device in the BEOL process with a temperature below 400° C. and without damaging the elements in the IC structure, which in turn increases the reliability of the IC structure. In addition, the resistive switching layer is made of the TMDC material, which in turn decreases a thickness of the resistive switching layer and acts as a nontoxic material to be environmentally friendly. Furthermore, because the resistive switching layer can be grown on the bottom electrode of RRAM device directly, there is no need to perform an additional transferring process on the resistive switching layer, and thus fabrication of the RRAM device structure will not result in additional processes that may damage the bottom electrode of the RRAM device and hence additional cost. Moreover, the RRAM device having a resistive switching layer including the TMDC material has a low operating voltage, which in turn improves the performance of the RRAM device.

In some embodiments, a method includes forming a first electrode layer on a substrate; depositing a transition metal layer on the first electrode layer; introducing a chalcogen precursor around the transition metal layer; performing a plasma treatment to ionize the chalcogen precursor around the transition metal layer to convert the transition metal layer into a transition metal dichalcogenide (TMDC) layer at a temperature lower than about 400° C.; forming a second electrode layer on the TMDC layer. In some embodiments, the plasma treatment is performed by a microwave plasma-enhanced chemical vapor deposition system. In some embodiments, the plasma treatment is performed at a frequency in a range from about 2000 MHz to about 3000 MHz. In some embodiments, the plasma treatment is performed at an operating power in a range from about 10 W to about 40 W. In some embodiments, the plasma treatment is performed under a pressure in a range from about 10⁻¹ to about 10⁻² torr. In some embodiments, the plasma treatment is performed at a process time duration less than about 30 minutes. In some embodiments, the chalcogen precursor comprises sulfur. In some embodiments, the first electrode layer is made of noble metal. In some embodiments, top electrode is made of aurum, argentum, copper, or combinations thereof. In some embodiments, the method further includes patterning the TMDC layer prior to forming the second electrode layer.

In some embodiments, a method includes forming a transistor on a substrate; forming a source/drain contact landing on a source/drain region of the transistor; forming a resistive random access memory (RRAM) structure on the source/drain contact. The RRAM structure includes a bottom metal electrode, a molybdenum disulfide layer, and a top metal electrode. The molybdenum disulfide layer is above the bottom metal electrode, in which the molybdenum disulfide layer has a forming voltage lower than about 0 V to form a conductive filament therein. The top metal electrode is above the molybdenum disulfide layer. In some embodiments, the molybdenum disulfide layer is formed by a plasma treatment on a molybdenum layer at a temperature lower than about 400° C. In some embodiments, the forming voltage is lower than about −2 V. In some embodiments, the RRAM structure has a set voltage being a positive value and lower than about 1.55 V. In some embodiments, the RRAM structure has a reset voltage being a negative value and lower than about 1.3 V in absolute.

In some embodiments, the semiconductor structure includes a semiconductor substrate, a gate structure, a source/drain contact, source/drain structures, a bottom electrode layer, a transition metal dichalcogenide (TMDC) memory layer, and a top electrode layer. The gate structure is on the semiconductor substrate. The source/drain structures are on opposite sides of the gate structure. The source/drain contact is on one of the source/drain structures. The bottom electrode layer is on the source/drain contact. The TMDC memory layer is on the bottom electrode layer. The TMDC layer has a thickness in a range from about 2 nm to about 10 nm. The top electrode layer is on the TMDC memory layer. In some embodiments, the TMDC memory layer is made of molybdenum disulfide, tungsten disulfide, molybdenum ditelluride, or combinations thereof. In some embodiments, the TMDC memory layer has a Raman spectrum including a A_{1g} mode and a E_{2g} mode, the A_{1g} mode having a full width at half maximum (FWHM) in a range from about 7 cm⁻¹ to about 11 cm⁻¹. In some embodiments, the bottom electrode layer is made of aurum, argentum, platinum, palladium, or combinations thereof. In some embodiments, the top electrode layer has a thickness in a range from about 10 nm to about 100 nm.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first electrode layer on a substrate;
depositing a transition metal layer on the first electrode layer;
introducing a chalcogen precursor around the transition metal layer;
performing a plasma treatment to ionize the chalcogen precursor around the transition metal layer to convert the transition metal layer into a transition metal dichalcogenide (TMDC) layer at a temperature lower than about 400° C.; and
forming a second electrode layer on the TMDC layer.

2. The method of claim 1, wherein the plasma treatment is performed by a microwave plasma-enhanced chemical vapor deposition system.

3. The method of claim 1, wherein the plasma treatment is performed at a frequency in a range from about 2000 MHz to about 3000 MHz.

4. The method of claim 1, wherein the plasma treatment is performed at an operating power in a range from about 10 W to about 40 W.

5. The method of claim 1, wherein the plasma treatment is performed under a pressure in a range from about 10⁻¹ to about 10⁻² torr.

6. The method of claim 1, wherein the plasma treatment is performed at a process time duration less than about 30 minutes.

7. The method of claim 1, wherein the chalcogen precursor comprises sulfur.

8. The method of claim 1, wherein the first electrode layer is made of noble metal.

9. The method of claim 1, wherein top electrode is made of aurum, argentum, copper, or combinations thereof.

10. The method of claim 1, further comprising:
patterning the TMDC layer prior to forming the second electrode layer.

11. A method, comprising:
forming a transistor on a substrate;
forming a source/drain contact landing on a source/drain region of the transistor;
forming a resistive random access memory (RRAM) structure on the source/drain contact, the RRAM structure comprising:
a bottom metal electrode;
a molybdenum disulfide layer above the bottom metal electrode, wherein the molybdenum disulfide layer has a forming voltage lower than about 0 V to form a conductive filament therein; and
a top metal electrode above the molybdenum disulfide layer.

12. The method of claim 11, wherein the molybdenum disulfide layer is formed by a plasma treatment on a molybdenum layer at a temperature lower than about 400° C.

13. The method of claim 11, wherein the forming voltage is lower than about −2 V.

14. The method of claim 11, wherein the RRAM structure has a set voltage being a positive value and lower than about 1.55 V.

15. The method of claim 11, wherein the RRAM structure has a reset voltage being a negative value and lower than about 1.3 V in absolute.

16. A semiconductor structure, comprising:
a semiconductor substrate;
a gate structure on the semiconductor substrate;
source/drain structures on opposite sides of the gate structure;
a source/drain contact landing on one of the source/drain structures;
a bottom electrode layer on the source/drain contact;
a transition metal dichalcogenide (TMDC) memory layer on the bottom electrode layer, the TMDC layer having a thickness in a range from about 2 nm to about 10 nm; and
a top electrode layer on the TMDC memory layer.

17. The semiconductor structure of claim 16, wherein the TMDC memory layer is made of molybdenum disulfide, tungsten disulfide, molybdenum ditelluride, or combinations thereof.

18. The semiconductor structure of claim 16, wherein the TMDC memory layer has a Raman spectrum including a A_{1g} mode and a E_{2g} mode, the A_{1g} mode having a full width at half maximum (FWHM) in a range from about 7 cm⁻¹ to about 11 cm⁻¹.

19. The semiconductor structure of claim 16, wherein the bottom electrode layer is made of aurum, argentum, platinum, palladium, or combinations thereof.

20. The semiconductor structure of claim 16, wherein the top electrode layer has a thickness in a range from about 10 nm to about 100 nm.
